(19) United States
(12) Patent Application Publication
(10) Pub. No.: US 2025/0220986 A1
(43) Pub. Date: Jul. 3, 2025

(54) AIRGAP SPACER WRAPPED AROUND A CONTACT

(71) Applicant: Intel Corporation, Santa Clara, CA (US)

(72) Inventors: Shao Ming Koh, Mountain View, OR (US); Sudipto Naskar, Portland, OR (US); Nikhil J. Mehta, Portland, OR (US); Dimitri Kioussis, San Jose, CA (US); Sachin S. Vaidya, Portland, OR (US)

(73) Assignee: Intel Corporation, Santa Clara, CA (US)

(21) Appl. No.: 18/397,210

(22) Filed: Dec. 27, 2023

(51) Int. Cl. H01L 29/06; H01L 27/092; H01L 29/417; H01L 29/423; H01L 29/66; H01L 29/775; H01L 29/778; H01L 29/786

(52) U.S. Cl. CPC H10D 62/116; H10D 30/43; H10D 30/47; H10D 30/6729; H10D 30/6735; H10D 30/6757; H10D 62/121; H10D 64/017; H10D 84/85

(57) ABSTRACT

Techniques are provided to form semiconductor devices that include an epitaxial contact with an airgap spacer surrounding a portion of the contact. Accordingly, the airgap spacer is between the contact and an adjacent gate structure and is between the contact and an adjacent dielectric structure. A semiconductor device includes a gate structure around or otherwise on a semiconductor region (or channel region) that extends from a first source or drain region to a second source or drain region. A dielectric structure may extend through an entire thickness of the gate structure and along the first direction to also be adjacent to the first and second source or drain regions. Conductive conducts are formed on one or both of the first source or drain region and the second source or drain region. An airgap spacer wraps around the entire perimeter of at least one of the conductive contacts.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors or adjacent conductive features becomes challenging. Accordingly, there remain a number of non-trivial challenges with respect to forming semiconductor devices.

### BRIEF DESCRIPTION OF THE DRAWINGS

FIG. 1A is an isometric view of an integrated circuit structure that includes airgaps that extend circumferentially around sides of contacts, in accordance with an embodiment of the present disclosure.

FIGS. 1B and 1C are different cross-sectional views of the integrated circuit of FIG. 1A that show the airgaps extending around the sides of a corresponding epitaxial contact along a first direction (1B) and along a second direction (1C), in accordance with an embodiment of the present disclosure.

FIGS. 2A and 2B are cross-sectional views that illustrate one stage in an example process for forming an integrated circuit configured with an airgap that extends circumferentially around sides of a contact structure, in accordance with an embodiment of the present disclosure.

FIGS. 3A and 3B are cross-sectional views that illustrate another stage in the example process for forming an integrated circuit configured with an airgap that extends circumferentially around sides of a contact structure, in accordance with an embodiment of the present disclosure.

FIGS. 4A and 4B are cross-sectional views that illustrate another stage in the example process for forming an integrated circuit configured with an airgap that extends circumferentially around sides of a contact structure, in accordance with an embodiment of the present disclosure.

FIGS. 5A and 5B are cross-sectional views that illustrate another stage in the example process for forming an integrated circuit configured with an airgap that extends circumferentially around sides of a contact structure, in accordance with an embodiment of the present disclosure.

FIGS. 6A and 6B are cross-sectional views that illustrate another stage in the example process for forming an integrated circuit configured with an airgap that extends circumferentially around sides of a contact structure, in accordance with an embodiment of the present disclosure.

FIGS. 7A and 7B are cross-sectional views that illustrate another stage in the example process for forming an integrated circuit configured with an airgap that extends circumferentially around sides of a contact structure, in accordance with an embodiment of the present disclosure.

FIGS. 8A and 8B are cross-sectional views that illustrate another stage in the example process for forming an integrated circuit configured with an airgap that extends circumferentially around sides of a contact structure, in accordance with an embodiment of the present disclosure.

FIGS. 9A and 9B are cross-sectional views that illustrate another stage in the example process for forming an integrated circuit configured with an airgap that extends circumferentially around sides of a contact structure, in accordance with an embodiment of the present disclosure.

FIGS. 10A and 10B are cross-sectional views that illustrate another stage in the example process for forming an integrated circuit configured with an airgap that extends circumferentially around sides of a contact structure, in accordance with an embodiment of the present disclosure.

FIGS. 11A and 11B are cross-sectional views that illustrate another stage in the example process for forming an integrated circuit configured with an airgap that extends circumferentially around sides of a contact structure, in accordance with an embodiment of the present disclosure.

FIGS. 12A and 12B are cross-sectional views that illustrate another stage in the example process for forming an integrated circuit configured with an airgap that extends circumferentially around sides of a contact structure, in accordance with an embodiment of the present disclosure.

FIGS. 13A and 13B are cross-sectional views that illustrate another stage in the example process for forming an integrated circuit configured with an airgap that extends circumferentially around sides of a contact structure, in accordance with an embodiment of the present disclosure.

FIGS. 14A and 14B are cross-sectional views that illustrate another stage in the example process for forming an integrated circuit configured with an airgap that extends circumferentially around sides of a contact structure, in accordance with an embodiment of the present disclosure.

FIGS. 15A and 15B are cross-sectional views that illustrate another stage in the example process for forming an integrated circuit configured with an airgap that extends circumferentially around sides of a contact structure, in accordance with an embodiment of the present disclosure.

FIGS. 16A and 16B are cross-sectional views that illustrate another stage in the example process for forming an integrated circuit configured with an airgap that extends circumferentially around sides of a contact structure, in accordance with an embodiment of the present disclosure.

FIGS. 17A and 17B are cross-sectional views that illustrate another stage in the example process for forming an integrated circuit configured with an airgap that extends circumferentially around sides of a contact structure, in accordance with an embodiment of the present disclosure.

FIGS. 18A and 18B are cross-sectional views that illustrate another stage in the example process for forming an integrated circuit configured with an airgap that extends circumferentially around sides of a contact structure, in accordance with an embodiment of the present disclosure.

FIGS. 19A and 19B are cross-sectional views that illustrate another stage in the example process for forming an integrated circuit configured with an airgap that extends circumferentially around sides of a contact structure, in accordance with an embodiment of the present disclosure.

FIG. 20 illustrates a cross-sectional view of a chip package containing one or more semiconductor dies, in accordance with some embodiments of the present disclosure.

FIG. 21 is a flowchart of a fabrication process for a semiconductor device having an airgap that extends circumferentially around sides of a contact structure, in accordance with an embodiment of the present disclosure.

FIG. 22 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include a contact with an airgap spacer surrounding a portion of the contact. In an example, the airgap spacer is between a source or drain contact and a gate structure along a first direction and is between the source or drain contact and a dielectric structure (e.g., a gate cut structure) along a second direction orthogonal to the first direction. The techniques can be used in any number of integrated circuit applications and are particularly useful with respect to device layer transistors, such as finFETs or gate-all-around transistors (e.g., ribbonFETs and nanowire FETs) or forksheet transistors (e.g., forksheet FET). In an example, a semiconductor device includes a gate structure around or otherwise on a semiconductor region (or channel region) that extends from a first source or drain region to a second source or drain region. The semiconductor regions can be, for example, fins of semiconductor material or one or more nanowires or nanoribbons or nanosheets of semiconductor material that extend between the first and second source or drain regions along a first direction while the gate structure extends over the semiconductor regions along a second direction. A dielectric structure may extend in a third direction through an entire thickness of the gate structure and along the first direction to also be adjacent to the first and second source or drain regions. Conductive conducts are formed on one or both of the first source or drain region and the second source or drain region. An airgap spacer wraps around the entire perimeter of at least one of the conductive contacts, according to some embodiments. The presence of the airgap spacer provides a relatively large region with a very low dielectric constant (e.g., around 1.0) between the contact and the adjacent gate structure (along the first direction) and between adjacent contacts (along the second direction), thus reducing the parasitic capacitance in the device. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example contact structures on source or drain regions are often densely packed close to one another and to adjacent transistor gate structures. To reduce parasitic capacitance, low-k dielectric materials can be used to separate the contacts from adjacent conductive structures, but even the dielectric constant associated with low-k dielectric materials can be relatively high and still cause parasitic capacitance. One possible solution is to form an airgap between the adjacent conductors, because an airgap has the lowest possible dielectric constant of around 1.0. An airgap can be formed between the contact and adjacent conductive structures by conformally depositing a dielectric material within a narrow trench and allowing the dielectric material to pinch-off at the top of the trench, thus leaving an airgap space in the middle of the trench. Unfortunately, the resulting airgap is relatively narrow (e.g., having a small lateral thickness that extends between the adjacent conductors). Moreover, the majority of the trench is still filled with the deposited dielectric having a relatively much higher dielectric constant than the airgap. Accordingly, the full vertical height and/or lateral width of the trench is not utilized by the airgap. In this manner, the resulting airgap is both inadequate in both its lateral thickness and its vertical height, and thus has a limited impact on reducing parasitic capacitance between the adjacent conductors.

Thus, and in accordance with an embodiment of the present disclosure, techniques are provided herein to form robust airgap structures adjacent to conductive contacts configured to provide adequate reduction of parasitic capacitance. For example, the airgap may have a greater lateral thickness between the contact and an adjacent conductor, relative to an airgap formed by pinch-off and/or have a predetermined height that is not dependent on a pinch-off process that yields a shorter and otherwise less predictable airgap vertical height. The airgap formation takes advantage of a thermal vaporization process to remove a sacrificial material from beneath an upper material to leave behind an airgap beneath the upper material. According to some such example embodiments, this process can also form the airgap circumferentially around all sides of the contact, such that the airgap is between the contact and an adjacent gate structure and also between the contact and another adjacent contact. In some examples, the sacrificial material may be a polymer-based material that is formed around all sidewalls of the contact, although other materials that can be selectively vaporized can be used. The polymer material may be recessed and a dielectric material is formed over the polymer material. Although the vaporization temperature can vary from embodiment to the next, depending on the sacrificial material used, the vaporization process for some examples using a polymer material can be carried out at a temperature of between about 300° C. and 500° C. In some such cases, the vaporization process outgasses through the upper dielectric material. This process leaves behind an airgap spacer in the volume previously occupied by the polymer material, and leverages a more significant portion of the width and height of the available space between the contact and adjacent conductive structures compared to prior techniques.

According to an embodiment, an integrated circuit includes a semiconductor device having a semiconductor region extending in a first direction from a source or drain region, and a gate structure extending in a second direction over the semiconductor region. A conductive contact is on a top surface of the source or drain region, and a dielectric structure extends along the first direction and through an entire thickness of the gate structure in a third direction such that the dielectric structure is spaced from the conductive contact along the second direction. An airgap is between the conductive contact and the gate structure along the first direction and between the conductive contact and the dielectric structure along the second direction.

According to another embodiment, an integrated circuit includes a first semiconductor device having a first semiconductor region extending in a first direction from a source or drain region, and a first gate structure extending in a second direction over the first semiconductor region. The integrated circuit further includes a second semiconductor device having a second semiconductor region extending in the first direction from an opposite side of the source or drain region compared to the first semiconductor region, and a second gate structure extending in the second direction over the second semiconductor region. The integrated circuit further includes a conductive contact on a top surface of the source or drain region, a first dielectric structure extending along the first direction through both the first gate structure and the second gate structure and through an entire thickness of both the first gate structure and the second gate structure in a third direction, and a second dielectric structure extending along the first direction through both the first gate structure and the second gate structure and through an entire thickness of both the first gate structure and the second gate structure in the third direction. The integrated circuit further includes an airgap around the conductive contact such that the airgap is between the conductive contact and the first gate structure along the first direction, between the conductive contact and the second gate structure along the first direction, between the conductive contact and the first dielectric structure along the second direction, and between the conductive contact and the second dielectric structure along the second direction.

According to another embodiment, a method of forming an integrated circuit includes: forming a fin comprising semiconductor material, the fin extending above a substrate and extending in a first direction; forming a dielectric layer adjacent to a subfin portion of the fin; forming source or drain regions at opposite ends of the fin; forming a dielectric fill over the source or drain regions; forming a gate structure on the dielectric layer and over the semiconductor material and extending in a second direction; recessing the dielectric fill over the source or drain region to form a contact recess that exposes a top surface of the source or drain region; forming a sacrificial material within the contact recess; forming a conductive contact over the sacrificial material within the contact recess; replacing the sacrificial material with a polymer material; recessing a top portion of the polymer material; forming a dielectric cap within the recessed area above the polymer material; and removing the polymer material via a vaporization process to leave behind an airgap in the volume previously occupied by the polymer material.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, implantation-doped portions of a given substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of airgaps along the edges of one or more source or drain contacts. The airgaps may have an atypically large lateral width (e.g., between 4 and 6 nm) due to their formation process. Furthermore, the airgaps may be observed to completely wrap around their respective contacts.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

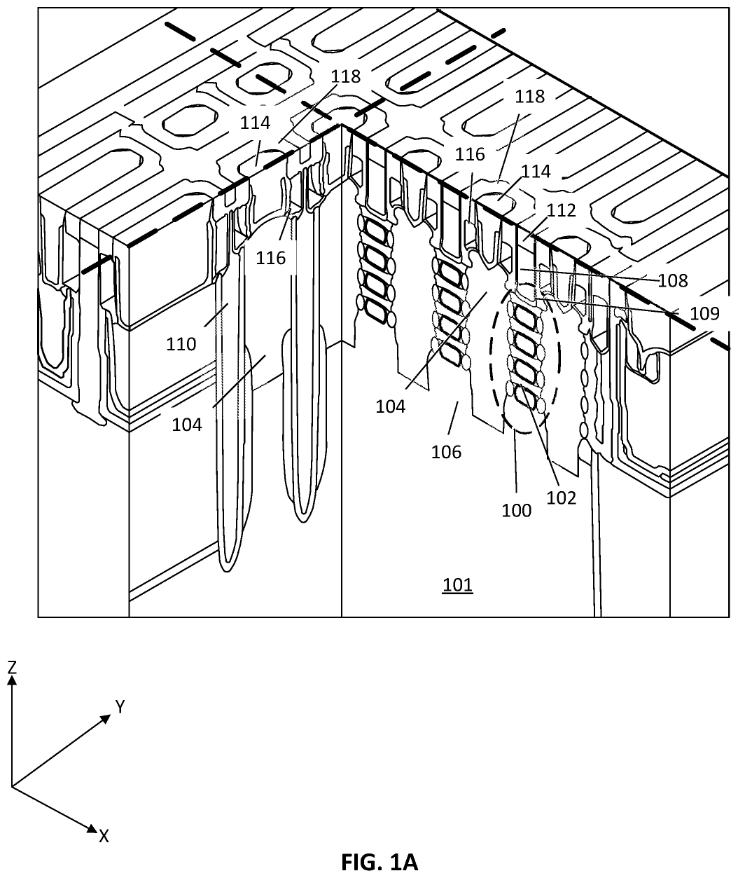

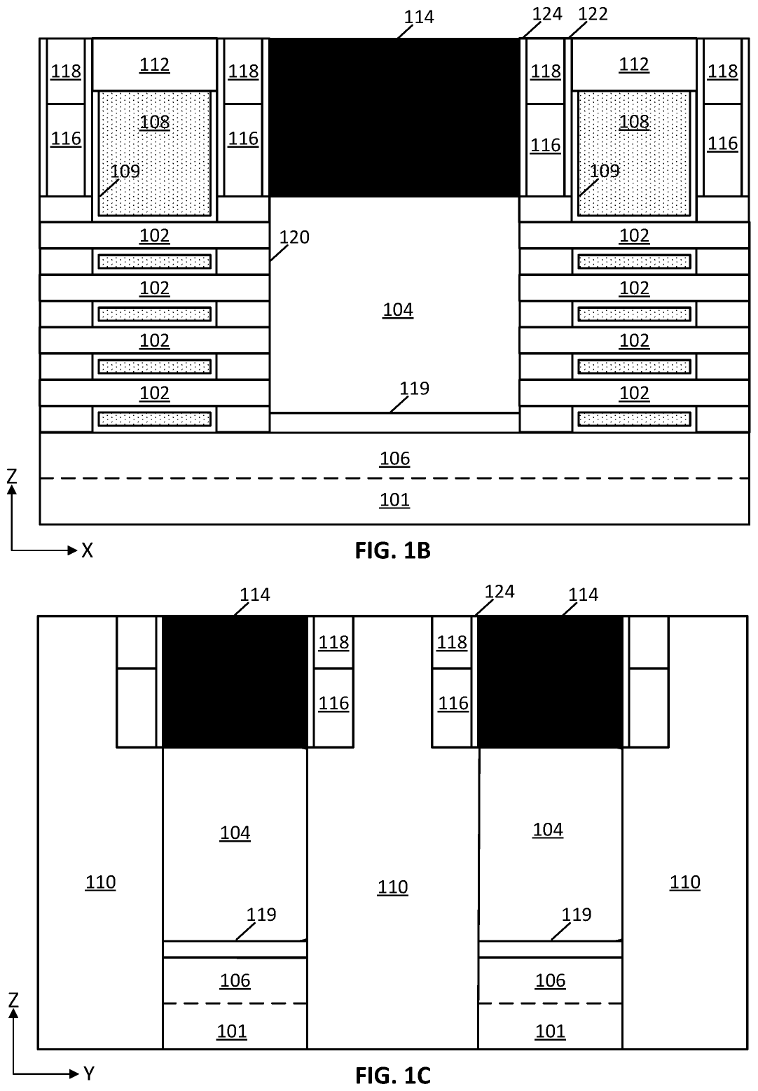

FIG. 1A is an isometric view of a portion of an integrated circuit that includes various semiconductor devices 100, in accordance with an embodiment of the present disclosure. Each of the semiconductor devices may be non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

The semiconductor material used in each of the semiconductor devices may be formed from a semiconductor substrate 101. Substrate 101 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of substrate 101 is removed and replaced with one or more backside interconnect layers to form backside signal and power routing.

The one or more semiconductor regions of the devices may include fins that can be, for example, native to substrate 101 (formed from the substrate itself), such as silicon fins etched from a bulk silicon substrate. Alternatively, the fins can be formed of material deposited onto substrate 101. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons during a gate forming process where one type of the alternating layers is selectively etched away so as to liberate the other type of alternating layers within the channel region, so that a gate-all-around process can then be carried out. Again, the alternating layers can be blanket deposited and then etched into fins or deposited into fin-shaped trenches.

Each semiconductor device 100 includes one or more semiconductor regions (sometimes called channel regions), such as one or more nanoribbons 102 extending between epitaxial source or drain regions 104 in a first direction along the X-axis. Other examples may have implantation-doped source or drain regions, rather than epitaxial source or drain regions. According to some embodiments, semiconductor devices 100 further include a subfin region 106 beneath nanoribbons 102. Other examples may have nanowires or nanosheets or a fin, for the channel regions, while yet other examples may have a planar transistor architecture (flat channel region). According to some embodiments, subfin region 106 is a portion of the corresponding semiconductor fin that remains after formation of the various transistors and may be formed from substrate 101. Accordingly, subfin region 106 may include the same semiconductor material as substrate 101 (or any semiconductor material in situations where substrate 101 is removed).

Any of source or drain regions 104 may act as either a source region or a drain region, depending on the application and dopant profile. Any semiconductor materials suitable for source and drain regions can be used (e.g., group IV and group III-V semiconductor materials) for any of the illustrated source or drains regions 104. In any such cases, the composition and doping of source or drain regions 104 may be the same or different, depending on the polarity of the transistors. For example, any semiconductor devices that are p-type MOS (PMOS) transistors have a high concentration of p-type dopants in the associated source or drain regions 104, and any semiconductor devices that are n-type MOS (NMOS) transistors have a high concentration of n-type dopants in the associated source or drain regions 104. Any number of source and drain configurations and materials can be used.

A gate structure that includes gate electrode 108 and a gate dielectric 109 extends over the one or more semiconductor regions of a given semiconductor device 100 in a second direction along the Y-axis to form the transistor gate. Gate electrode 108 may represent any number of conductive layers and gate dielectric 109 may represent any number of dielectric layers. Gate electrode 108 may include any sufficiently conductive material such as a metal, metal alloy, or doped polysilicon. In some embodiments, gate electrode 108 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate electrode 108 may also include a fill metal or other conductive material around the workfunction metals to provide the whole gate electrode structure. Gate dielectric 109 may include any suitable gate dielectric material(s). In some embodiments, gate dielectric 109 includes a layer of native oxide material (e.g., silicon dioxide) on the nanoribbons 102 or other semiconductor regions, and a layer of high-k dielectric material (e.g., hafnium oxide) on the native oxide.

According to some embodiments, adjacent gate electrodes 108 that are coaxially aligned along the second direction (e.g., along the Y-axis) may be separated from one another by a dielectric wall 110 (or dielectric structure). Any number of suitable dielectric materials and/or layers can be used for dielectric wall 110, such as silicon nitride or silicon oxynitride or low-K versions of these (e.g., porous silicon oxynitride). Any number of dielectric walls 110 may run lengthwise parallel to one another along the X-axis and extend along the Z-axis at least through an entire thickness of the gate structures. According to some embodiments, dielectric walls 110 continues to extend along the X-axis between multiple pairs of semiconductor devices and between the source or drain regions 104 of the devices as described in more detail below. In some embodiments, dielectric walls 110 include a dielectric liner along its edges and a dielectric fill on the dielectric liner. The dielectric fill may have a lower dielectric constant compared to the dielectric liner.

According to some embodiments, a dielectric gate cap 112 is present along a top surface of gate electrode 108. Accordingly, dielectric gate cap 112 may run lengthwise along the Y-axis on the top surface of gate electrode 108. Dielectric gate cap 112 may include the same dielectric material as dielectric wall 110, in some examples. In some embodiments, dielectric gate cap 112 includes silicon nitride.

According to some embodiments, a conductive contact 114 is on a corresponding source or drain region 104. Any number of source or drain regions 104 may include a respective conductive contact 114 on its top surface. Each conductive contact 114 can include any suitable conductive fill material, such as tungsten, molybdenum, ruthenium, cobalt, or other metals. The contacts 114 may include just a conductive fill material in some cases, while in other cases may include one or more conductive liner layers 115 in addition to conductive fill material (such as shown in the example of FIG. 1A). The one or more conductive liner layers 115 may be used, for example, to reduce contact resistance or improve adhesion. Example liner materials include, for instance, titanium or tantalum, or a titanium or tantalum nitride. Any number of conductive contact structures can be used in conjunction with the techniques described herein.

Conductive contacts 114 may be densely arranged close to one another along the Y-axis and close to adjacent gate electrodes 108 along the X-axis. To mitigate or otherwise reduce the parasitic capacitance between these adjacent conductive structures, airgaps 116 are formed around the perimeter of conductive contacts 114 or at least along both the X-axis and the Y-axis, according to some embodiments. Airgaps 116 include a very low dielectric constant of around 1.0, thus lowering the parasitic capacitance when compared to using other low-k dielectric materials (e.g., porous silicon dioxide). It should be understood that the term ‘airgap’ does not imply that the region is filled with air. For example, the airgap may be a region under vacuum pressure that is substantially devoid of any gaseous elements, or only includes inert gases such as nitrogen and/or argon. According to some embodiments, airgaps 116 exist between a given contact 114 and an adjacent gate electrode 108 along the X-direction and also exist between the given contact 114 and an adjacent dielectric wall 110.

As seen in FIG. 1A, dielectric wall 110 may have a thinned dimension along the Y-axis between adjacent airgaps 116. In this manner, note that the adjacent airgaps 116 extend into an upper portion of dielectric wall 110, to cause such thinning. According to some examples, airgaps 116 may have a lateral thickness extending outward from contact 114 between about 4 nm and about 10 nm (e.g., 4 nm to 6 nm). Airgaps of this size are difficult to obtain using pinch-off based techniques. Moreover, note the height of the airgaps 116 can be well-controlled, as will be explained in turn.

According to some embodiments, a dielectric cap 118 is present over airgap 116. Dielectric cap 118 may follow airgap 116 around an entire perimeter of contact 114. Dielectric cap 118 may be any suitable dielectric material, such as silicon nitride. In some examples, dielectric cap 118 includes the same dielectric material as dielectric gate cap 112. A top surface of dielectric cap 118 may be coplanar with a top surface of dielectric gate cap 112 and/or a top surface of contact 114.

FIG. 1B illustrates a cross-section view across the XZ plane identified by the dashed line along the X-axis in FIG. 1A, according to an embodiment. A dielectric structure 119 may be present beneath source or drain regions 104 to isolate source or drain regions 104 from substrate 101. Dielectric structure 119 may include any number of dielectric layers and/or materials, such as silicon dioxide, silicon nitride, or silicon oxynitride.

According to some embodiments, inner spacers 120 are present between ends of adjacent nanoribbons 102 along the Z-direction. Inner spacers 120 may be any suitable dielectric material, such as silicon nitride, and provide separation between a given gate structure and the adjacent source or drain region 104. In some embodiments, inner spacers 120 are part of a larger sidewall spacer structure that runs along the gate structure sidewalls in the second direction (e.g., along the Y-axis) and extends the entire height of the gate structure along the Z-axis.

According to some embodiments, sidewalls of the upper portions of the gate structure (e.g., adjacent to contact 114) include a first dielectric liner 122 and similarly, sidewalls of contact 114 include a second dielectric liner 124. Airgaps 116 may be between first dielectric liner 122 and second dielectric liner 124 along the first direction (e.g., along the X-axis). Each of first and second dielectric liner 122/124 may include any suitable dielectric material, such as silicon nitride. Such liners may be made as thin as possible to maximize the space used by airgaps 116. Accordingly, first and second dielectric liner 122/124 may have thicknesses of less than 2 nm or less than 1 nm.

FIG. 1C illustrates another cross-section view across the YZ plane identified by the dashed line along the Y-axis in FIG. 1A, according to an embodiment. Second dielectric liner 124 is observed along the sidewalls of contact 114 between contact 114 and the adjacent dielectric wall 110. Note that dielectric wall 110 as illustrated here may represent any number of dielectric layers and materials. A top portion of dielectric wall 110 may be thinner along the second direction (e.g., along the Y-axis) compared to portions of dielectric wall 110 directly adjacent to source or drain regions 104.

### Fabrication Methodology

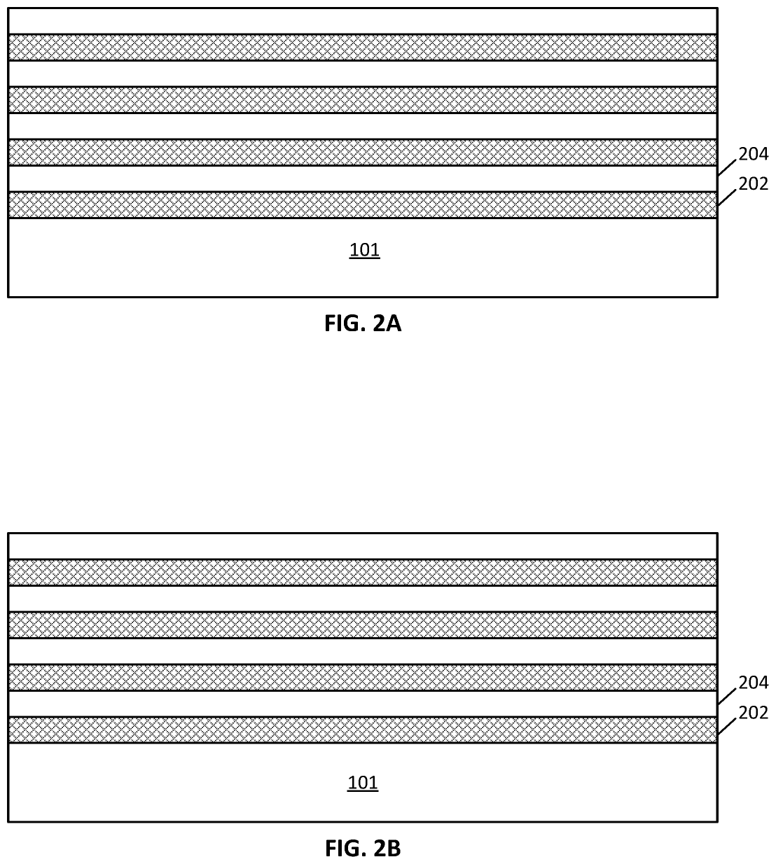

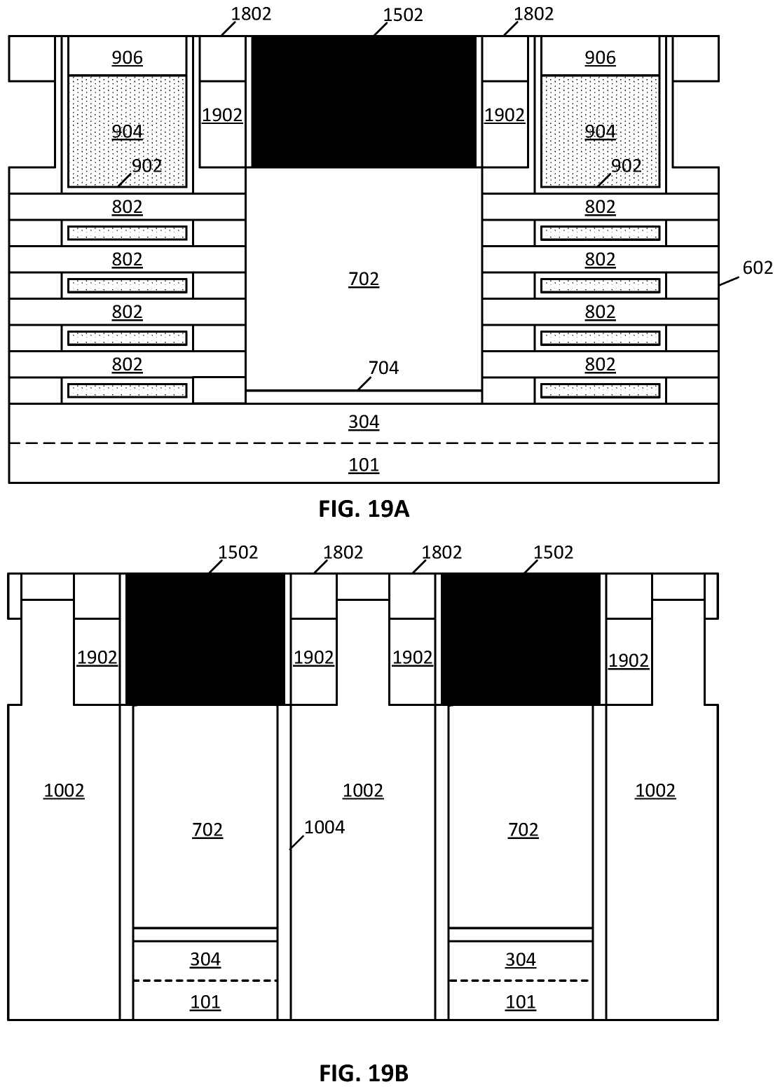

FIGS. 2A-19A and 2B-19B include cross-sectional views that collectively illustrate an example process for forming an integrated circuit configured with an airgap around a source or drain contact, in accordance with an embodiment of the present disclosure. FIGS. 2A-19A represent a similar cross-sectional view taken across the XZ plane in FIG. 1A, while FIGS. 2B-19B represent a cross-sectional view taken across the YZ plane in FIG. 1A. Each set of figures sharing the same letter shows an example structure that results from the process flow up to that point in time, so the depicted structure evolves as the process flow continues, culminating in the structure shown in FIGS. 19A-19B, which is similar to the structure shown in FIGS. 1B and 1C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 2A and 2B each illustrates a cross-sectional view taken through substrate 101 having a series of material layers formed over the substrate, according to an embodiment of the present disclosure. Alternating material layers may be deposited over substrate 101 including sacrificial layers 202 alternating with semiconductor layers 204. The alternating layers are used to form GAA transistor structures. Any number of alternating sacrificial layers 202 and semiconductor layers 204 may be deposited over substrate 101.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202. In some examples, sacrificial layers 202 may be doped with either n-type dopants (to produce a p-channel transistor) or p-type dopants (to produce an n-channel transistor).

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

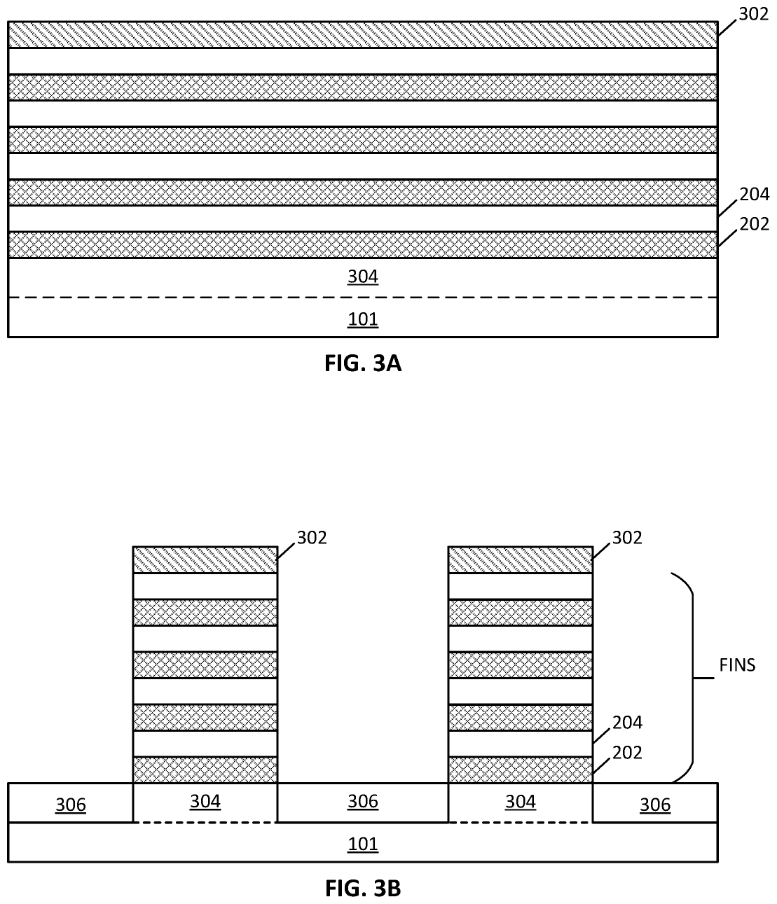

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 101. Portions of substrate 101 beneath the fins are not etched and yield subfin regions 304. The etched portion of substrate 101 may be filled with a dielectric fill 306 that acts as shallow trench isolation (STI) between adjacent fins. Dielectric fill 306 may be any suitable dielectric material such as silicon dioxide. Subfin regions 304 represent remaining portions of substrate 101 between dielectric fill 306, according to some embodiments. Note that the illustrations are not intended to be drawn to scale to enhance the clarity of certain features. For example, subfin regions 304 may have a greater height, such as a height that is around the same height as the stack of alternating semiconductor layers 204 and sacrificial layers 202, or a height that is greater than the height of the stack of alternating semiconductor layers 204 and sacrificial layers 202.

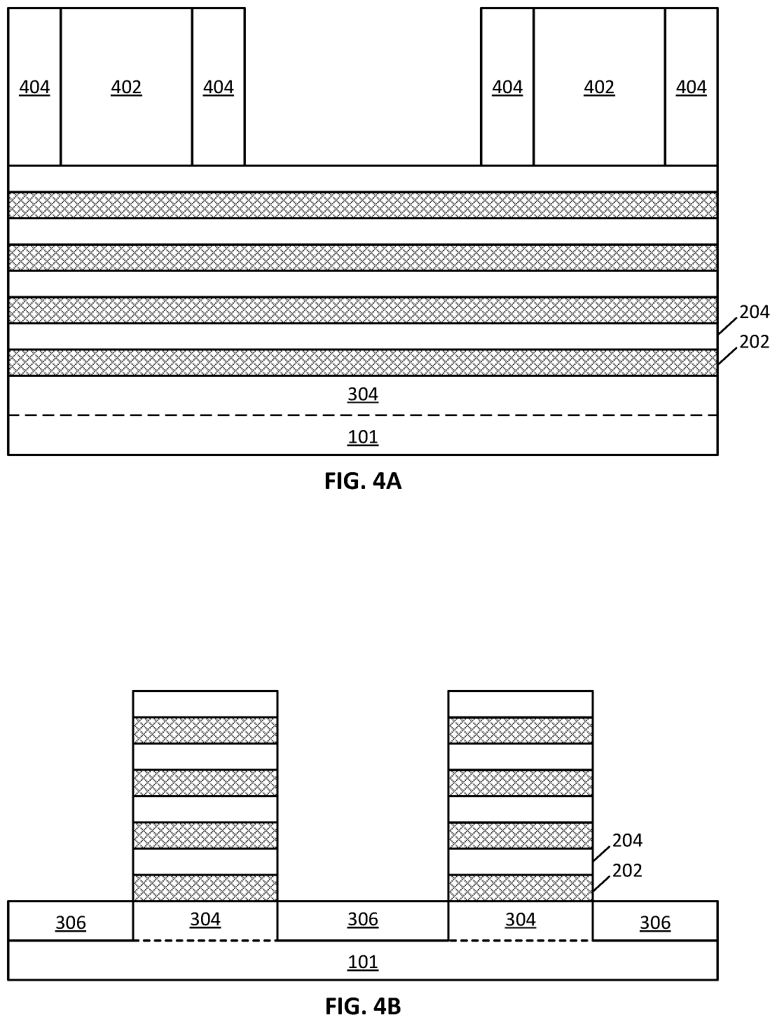

FIGS. 4A and 4B depict cross-section views of the structures shown in FIGS. 3A and 3B following the formation of sacrificial gates 402, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gates 402 may be any suitable material that can be selectively removed without damaging the semiconductor material of the fins. In some examples, sacrificial gates 402 include polysilicon.

According to some embodiments, spacer structures 404 are formed along the sidewalls of sacrificial gates 402. Spacer structures 404 may be deposited and then etched back such that spacer structures 404 remain mostly only on sidewalls of any exposed structures. In the cross-section view of FIG. 4B, spacer structures 404 may also be formed along sidewalls of the exposed fins over dielectric fill 306. Such sidewall spacers on the fins can be removed during later processing when forming the source or drain regions (or can remain around the edges of the formed source or drain regions). According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 306 comprises an oxide, so as to provide a degree of etch selectivity during final gate processing. Other etch selective dielectric schemes (e.g., oxide/carbide, carbide/nitride) can be used as well for spacer structures 404 and dielectric fill 306. In other embodiments, spacer structures 404 and dielectric fill 306 are compositionally the same or otherwise similar, where etch selectivity is not employed.

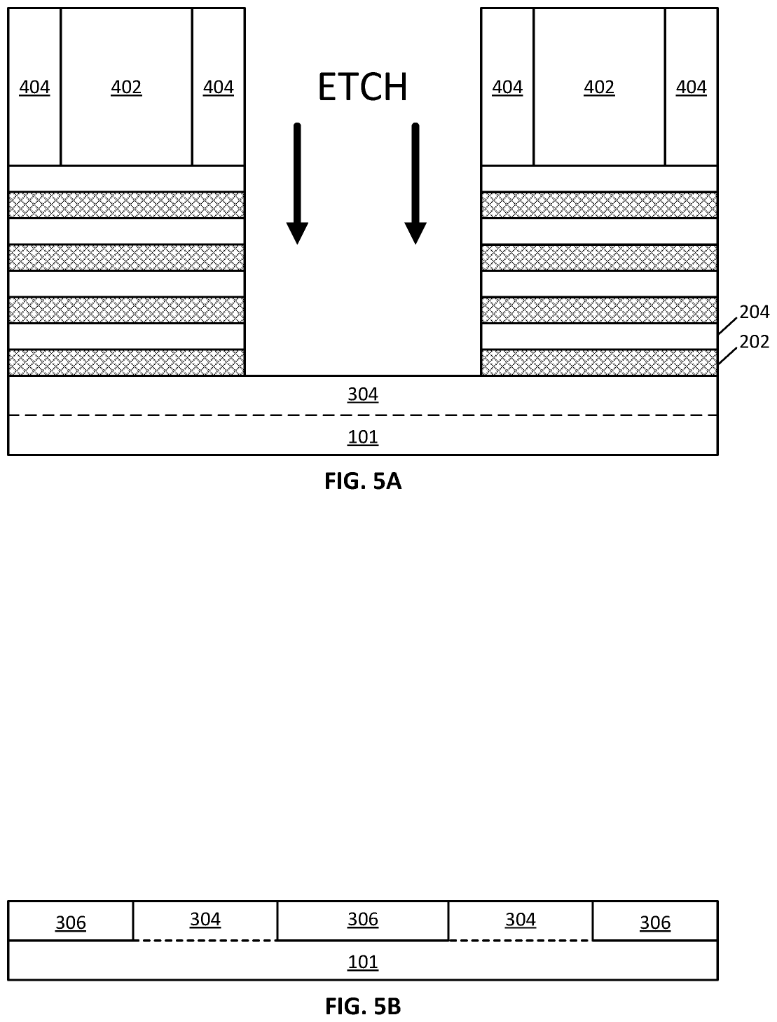

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE). The removal of the exposed fin portions creates source or drain trenches that alternate with gate trenches (currently filled with sacrificial gates 402) along the first direction, according to some embodiments. In some embodiments, at least a portion of subfin regions 304 are also removed such that a top surface of subfin regions 304 is recessed below a top surface of dielectric fill 306. The recessed area above subfin regions 304 may be filled with one or more dielectric materials.

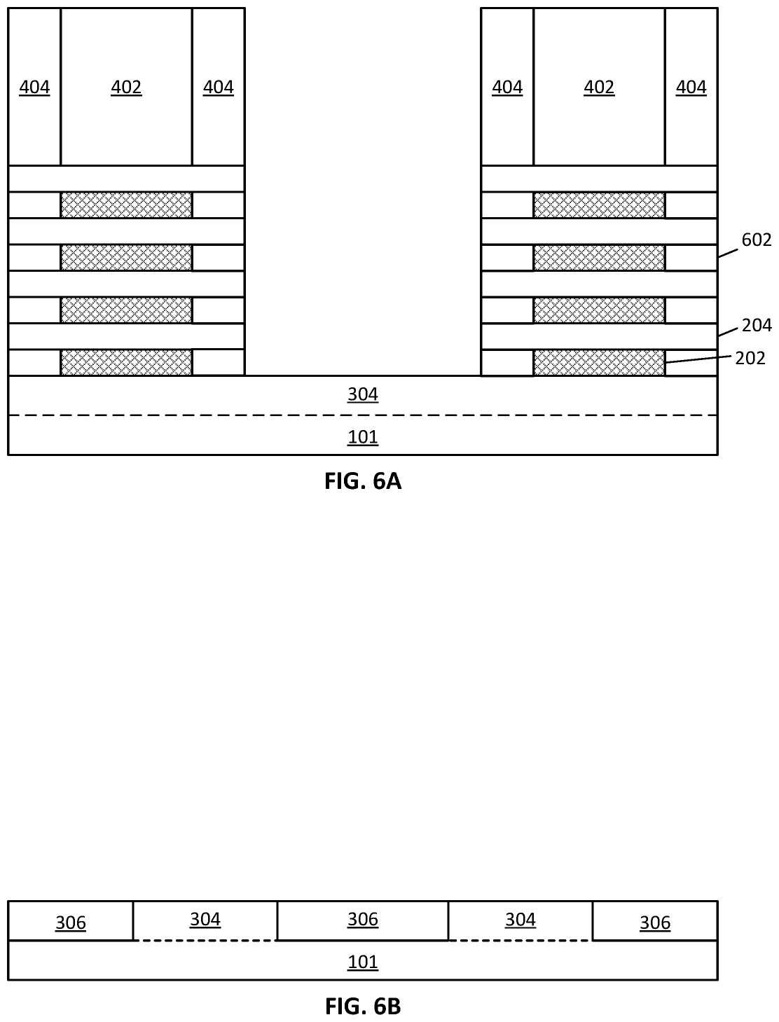

FIGS. 6A and 6B depict cross-section views of the structures shown in FIGS. 5A and 5B following the removal of portions of sacrificial layers 202 and subsequent formation of inner spacers 602, according to an embodiment of the present disclosure. An isotropic etching process may be used to selectively recess the exposed ends of each sacrificial layer 202 (e.g., while etching comparatively little of semiconductor layers 204). Inner spacers 602 may have a material composition that is similar to or the exact same as spacer structures 404. Accordingly, inner spacers 602 may be any suitable dielectric material that exhibits high etch selectively to semiconductor materials such as silicon and/or silicon germanium. Inner spacers 602 may be, for example, conformally deposited over the sides of the fin structure using a conformal deposition process like CVD or ALD and then etched back using an isotropic etching process to expose the ends of semiconductor layers 204. According to some embodiments, inner spacers 602 have a similar width (e.g., along the first direction) to spacer structures 404.

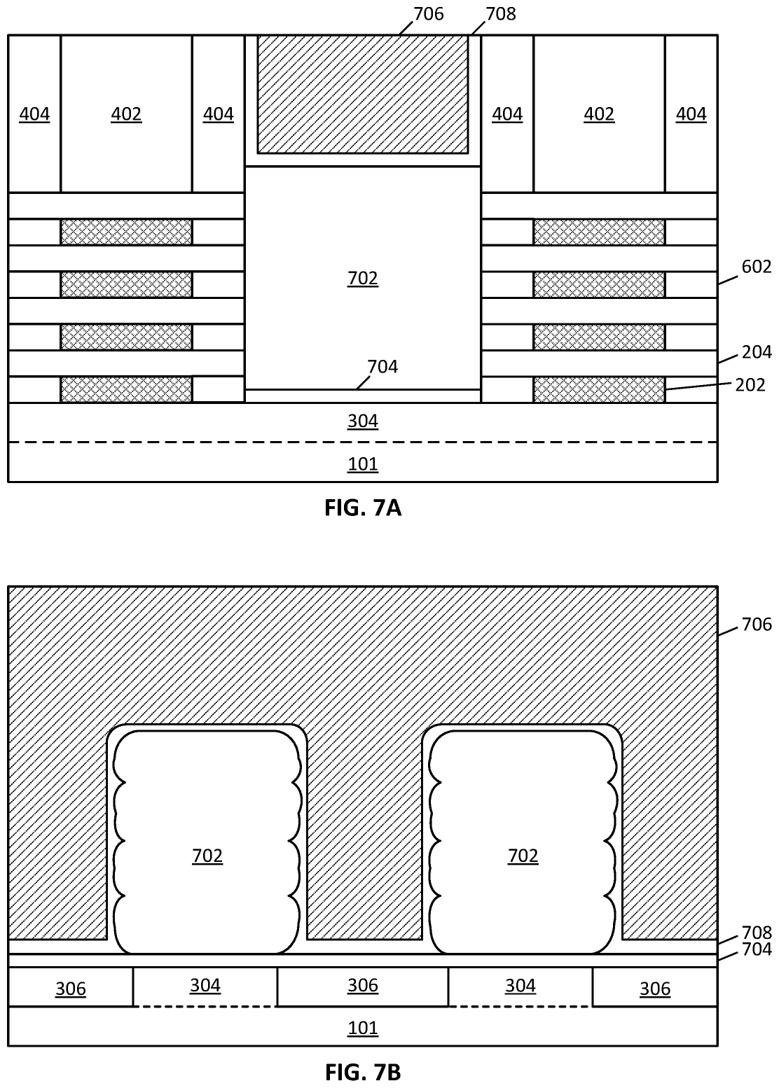

FIGS. 7A and 7B depict cross-section views of the structure shown in FIGS. 6A and 6B, respectively, following the formation of source or drain regions 702 within the source/drain trenches, according to some embodiments. Source or drain regions 702 may be formed in the areas that had been previously occupied by the exposed fins between spacer structures 404. According to some embodiments, source or drain regions 702 are epitaxially grown from the exposed semiconductor material at the ends of semiconductor layers 204. In some example embodiments, source or drain regions 702 are NMOS source or drain regions (e.g., epitaxial silicon) or PMOS source or drain regions (e.g., epitaxial SiGe). In some examples, a bottom dielectric layer 704 is formed within the source/drain trench prior to the formation of source or drain regions 702. Bottom dielectric layer 704 can include any suitable dielectric material, such as silicon dioxide.

According to some embodiments, a dielectric fill 706 is provided between adjacent source or drain regions 702. In some examples, dielectric fill 706 occupies a remaining volume within the source/drain trench around and over source or drain regions 702. Dielectric fill 706 may be any suitable dielectric material, such as silicon dioxide. In some examples, dielectric fill 706 extends up to and planar with a top surface of spacer structures 404 (e.g., following a polishing procedure). According to some embodiments, a dielectric liner 708 is formed within the source/drain trench prior to the formation of dielectric fill 706. Accordingly, dielectric liner 708 may be formed around any exposed surfaces of source or drain regions 702 and along sidewalls of the source/drain trench. To provide etch selectivity, dielectric liner 708 includes a different dielectric material than dielectric fill 706. For example, dielectric fill 706 may be silicon dioxide while dielectric liner 708 may be silicon nitride.

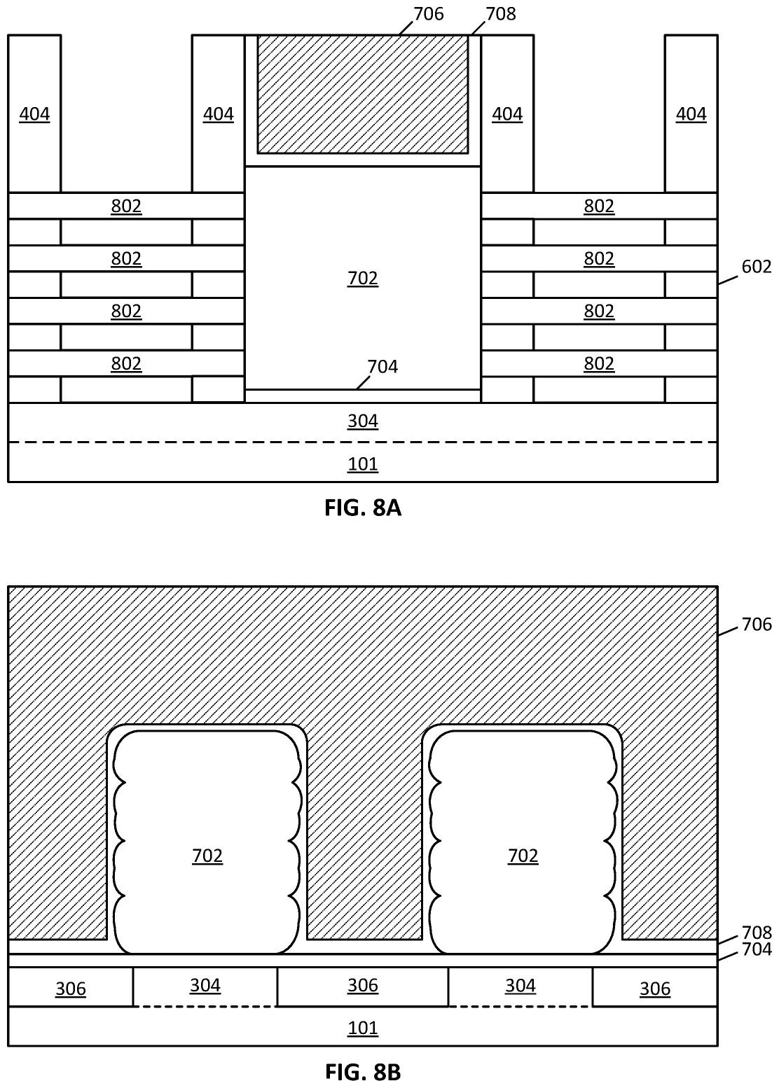

FIGS. 8A and 8B depict cross-section views of the structure shown in FIGS. 7A and 7B, respectively, following the removal of sacrificial gates 402 and sacrificial layers 202, according to some embodiments. In examples where gate masking layers are still present, they would be removed at this time. Once sacrificial gates 402 are removed, the fins extending between spacer structures 404 are exposed.

In the example where the fins include alternating semiconductor layers, sacrificial layers 202 are selectively removed to leave behind nanoribbons 802 that extend between corresponding source or drain regions 702. Each vertical set of nanoribbons 802 represents the semiconductor region of a different semiconductor device. It should be understood that nanoribbons 802 may also be nanowires or nanosheets. Sacrificial gates 402 and sacrificial layers 202 may be removed using the same isotropic etching process or different isotropic etching processes.

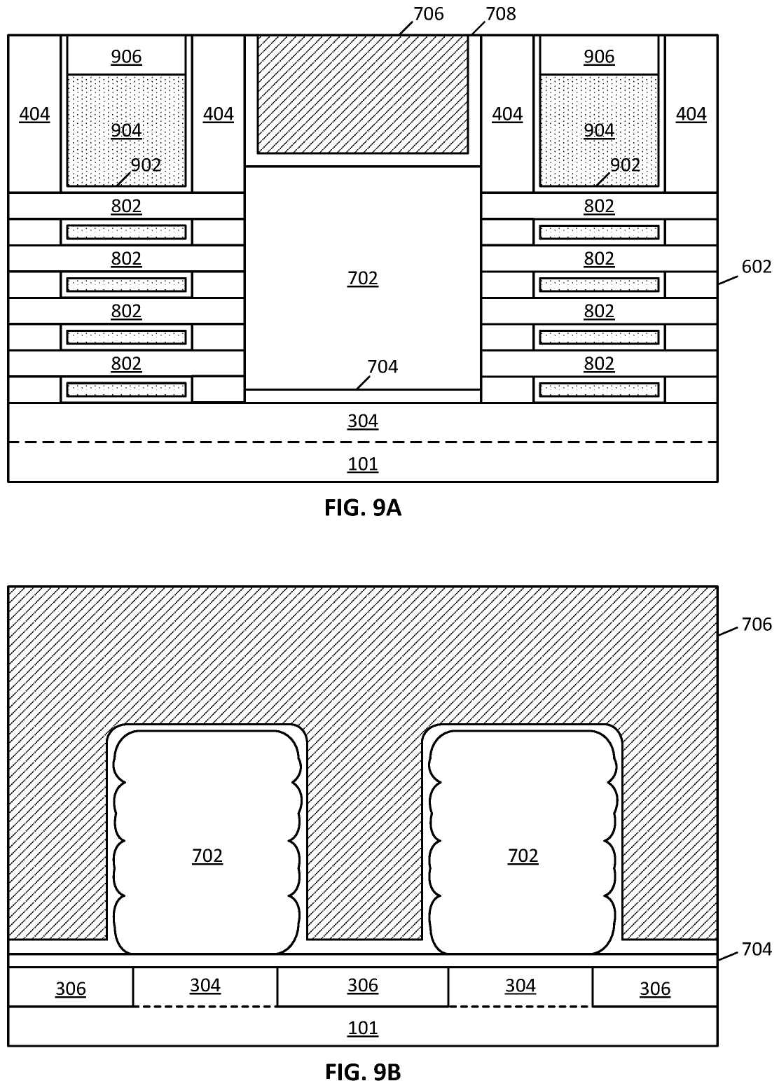

FIGS. 9A and 9B depict cross-section views of the structure shown in FIGS. 8A and 8B, respectively, following the formation of a gate structure, which includes a gate dielectric 902 and a gate electrode 904, and subsequent gate cap 906, according to some embodiments. Gate dielectric 902 may be first formed around nanoribbons 802 prior to the formation of gate electrode 904, which may include one or more conductive layers. Gate dielectric 902 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 902 includes a layer of hafnium oxide with a thickness between about 1 nm and about 5 nm. In some embodiments, gate dielectric 902 may include one or more silicates (e.g., titanium silicate, tungsten silicate, niobium silicate, and silicates of other transition metals). In some cases, gate dielectric 902 includes a first layer on nanoribbons 802, and a second layer on the first layer. The first layer can be, for instance, an oxide of the semiconductor material of nanoribbons 802 (e.g., silicon dioxide) and the second layer can be a high-k dielectric material (e.g., hafnium oxide).

The one or more conductive layers that make up gate electrode 904 may be deposited using electroplating, electroless plating, CVD, PECVD, ALD, or PVD, to name a few examples. In some embodiments, gate electrode 904 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 904 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

Gate cap 906 may be formed by first recessing gate electrode 904 and filling the recess with a dielectric material. The dielectric material may then be polished such that its top surface is substantially coplanar with a top surface of spacer structures 404 and dielectric fill 706.

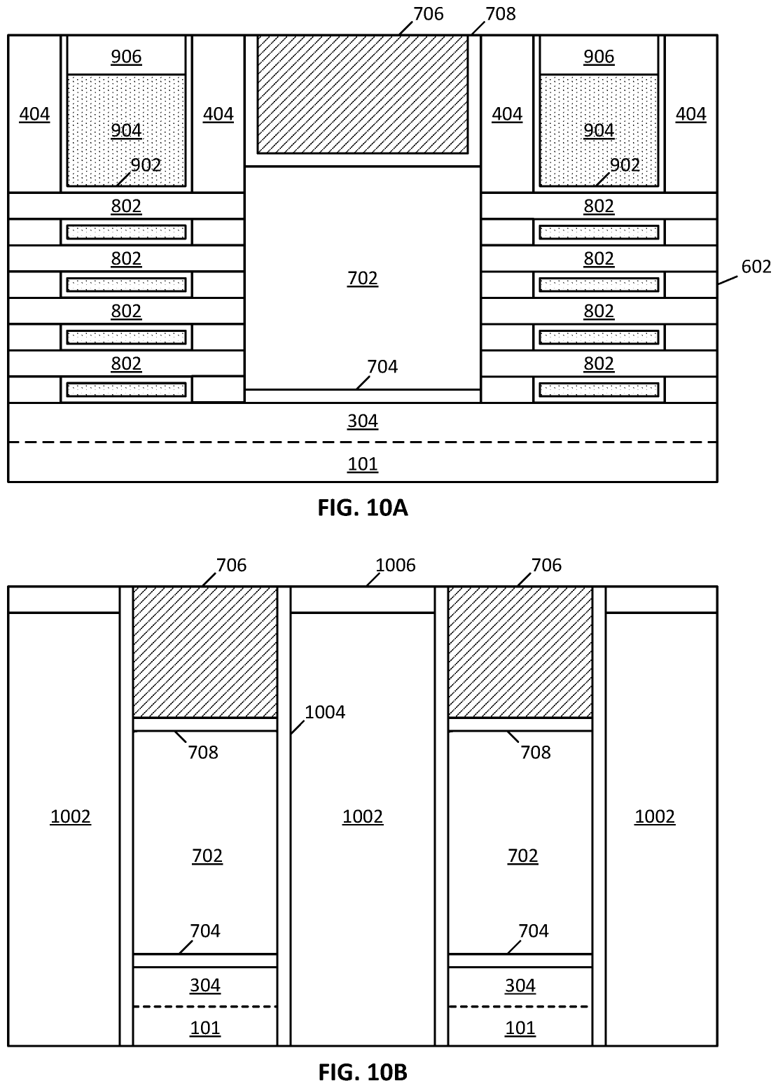

FIGS. 10A and 10B depict cross-section views of the structure shown in FIGS. 10A and 10B, respectively, following the formation of dielectric walls extending in the first direction between devices, according to some embodiments. The dielectric walls may include a dielectric fill 1002 on a dielectric liner 1004. According to some embodiments, the dielectric walls extend to a depth at least through an entire thickness of the gate structures to isolate separate gate structures along the second direction. The dielectric walls also extend in the first direction to be between adjacent source or drain regions 702 as shown in FIG. 10B. In the illustrated example, the dielectric walls directly abut the adjacent source or drain regions 702. In some other embodiments, the dielectric walls are narrower such that a portion of dielectric fill 706 remains between the dielectric walls and the adjacent source or drain regions 702. In some embodiments, the dielectric walls extend into at least a portion of dielectric fill 306 or through an entire thickness of dielectric fill 306. In some embodiments, the dielectric walls extend entirely through dielectric fill 306 and into a portion of substrate 101.

According to some embodiments, the dielectric walls may be formed by first forming corresponding gate cut recesses running orthogonally through alternating gate trenches and source/drain trenches, where the recesses have a relatively high aspect ratio (e.g., aspect ratio of 5:1 or higher, or 10:1 or higher). As shown in FIG. 9B, the gate cut recesses may extend between adjacent source or drain regions 702 and may expose portions of the source or drain regions. The gate cut recesses may be filled with one or more dielectric materials to form the dielectric walls. In the illustrated example, the dielectric walls include dielectric liner 1004 deposited first and dielectric fill 1002 formed on dielectric liner 1004. Dielectric liner 1004 may include a high-k dielectric material (e.g., materials with a dielectric constant higher than that of silicon dioxide or higher than 3.9) while dielectric fill 1002 may include a low-k dielectric material (e.g., materials with a dielectric constant equal to or lower than that of silicon oxide, such as porous silicon oxide, or equal to or lower than 3.9). According to some embodiments, dielectric fill 1002 may be recessed with a top dielectric layer 1006 formed in the recessed area. Top dielectric layer 1006 may have the same dielectric material as dielectric liner 1004 and have a different dielectric material than dielectric fill 1002 and/or dielectric fill 706.

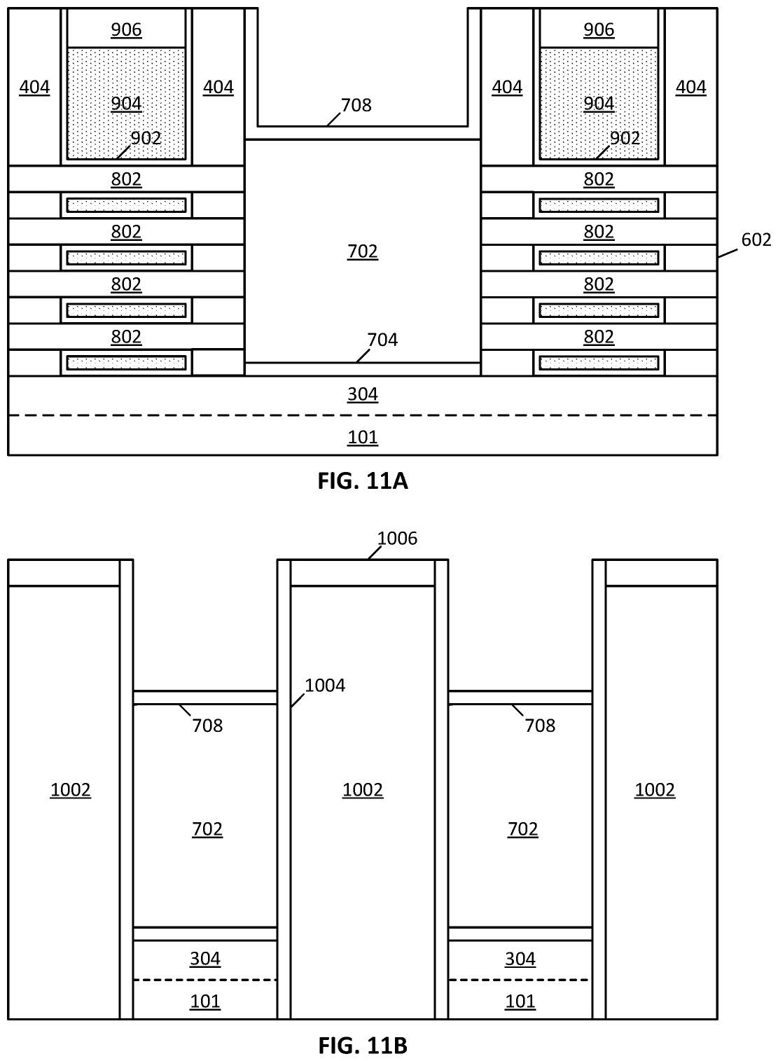

FIGS. 11A and 11B depict cross-section views of the structure shown in FIGS. 10A and 10B, respectively, following the removal of dielectric fill 706 from above source or drain regions 702 along the source/drain trenches, according to some embodiments. Source or drain regions 702 may be protected by dielectric liner 708 while dielectric fill 1002 of the dielectric walls is protected by both dielectric liner 1004 and top dielectric layer 1006. Dielectric fill 706 may be removed using a suitable isotropic etching process that etches substantially little or none of the material from dielectric liner 708, dielectric liner 1004, and top dielectric layer 1006.

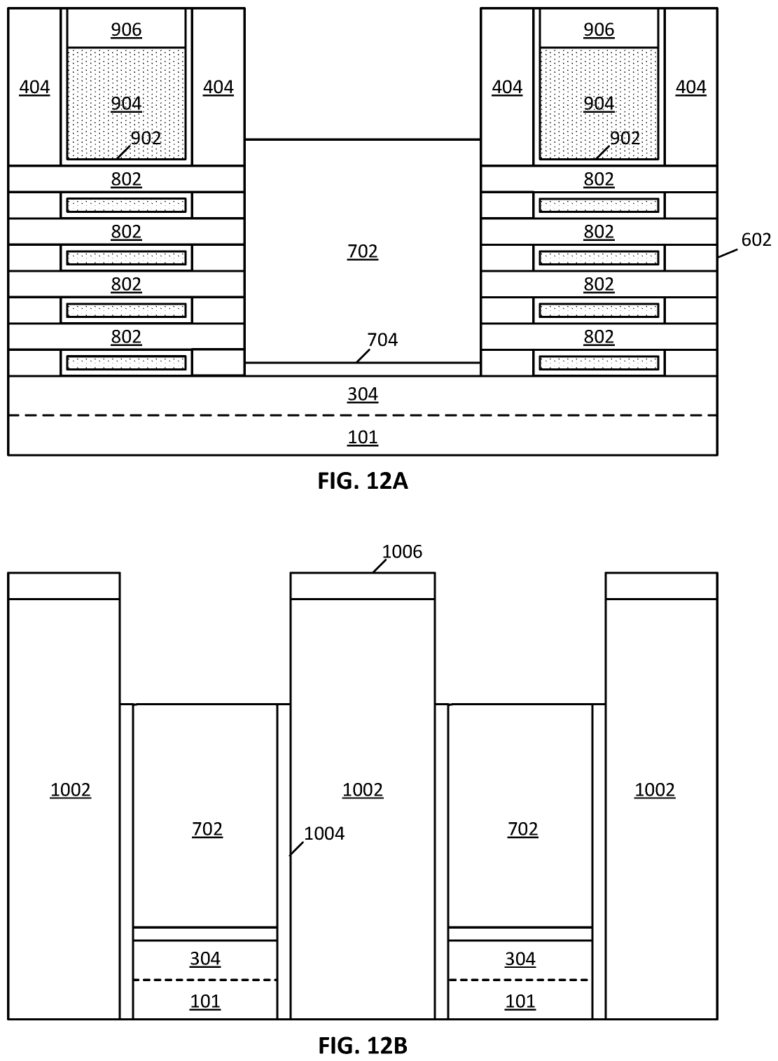

FIGS. 12A and 12B depict cross-section views of the structure shown in FIGS. 11A and 11B, respectively, following the removal of the exposed portions of dielectric liner 708 and dielectric liner 1004 within the source/drain trenches above source or drain regions 702, according to some embodiments. A hot phosphorous etch may be used to remove the silicon nitride material. According to some embodiments, one or more masking structures may be formed over dielectric gate cap 906 and/or over top dielectric layer 1006 to protect them during this etching process. It should be noted that top dielectric layer 1006 may be laterally etched partially during this process.

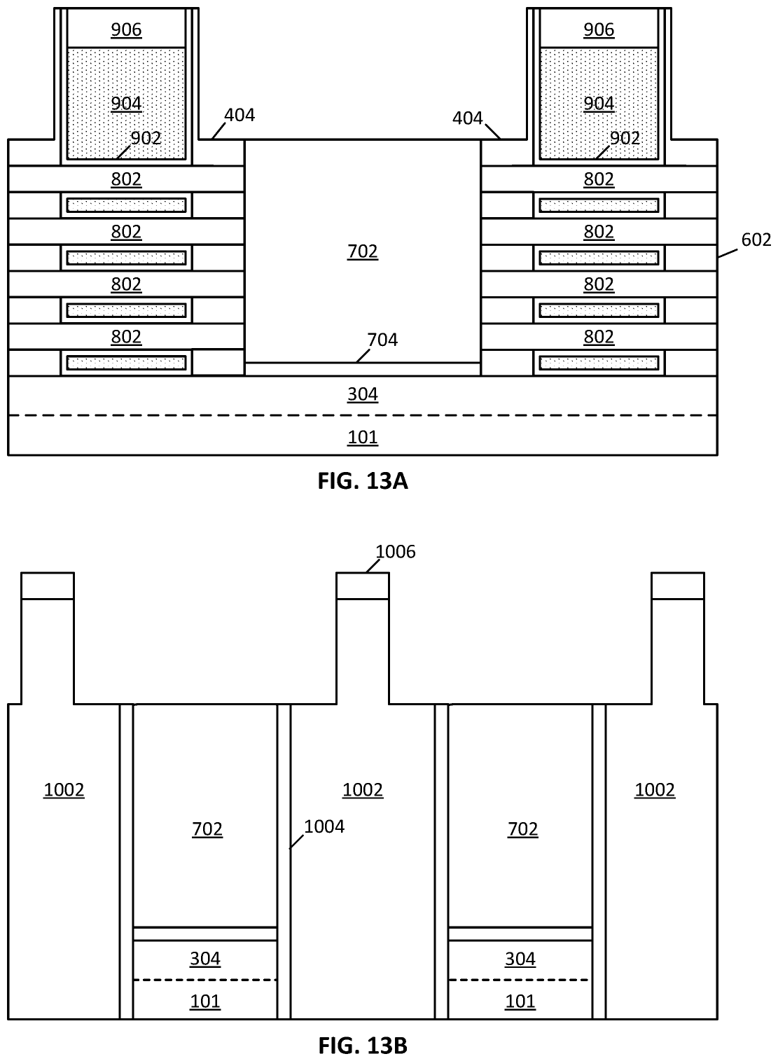

FIGS. 13A and 13B depict cross-section views of the structure shown in FIGS. 12A and 12B, respectively, following the partial removal of spacer structures 404 and the dielectric walls to create a larger contact area over the source or drain regions 702, according to some embodiments. The contact area within the source/drain trench is made wider along both the first direction and the second direction, according to some embodiments. The widening may be performed using any number of dielectric etches depending on what dielectric materials are exposed. In some embodiments, spacer structures 404 represent a plurality of dielectric layers on the sidewalls of the gate structures. For example, spacer structures 404 may include one or more silicon dioxide layers sandwiched between silicon nitride layers or other suitable dielectric materials with a high etch selectivity against one another. In this way, portions of spacer structures 404 can be stripped away by removing corresponding layers of spacer structures 404, thus widening the contact area above source or drain regions 702 along the first direction (FIG. 13A).

Turning to FIG. 13B, the exposed portions of dielectric fill 1002 from the dielectric walls may be removed using any suitable isotropic etch. In some embodiments, portions of top dielectric layer 1006 may also be etched back (as illustrated). However, in some embodiments, top dielectric layer 1006 may extend outwards past the thinned top portion of dielectric fill 1002 along the second direction.

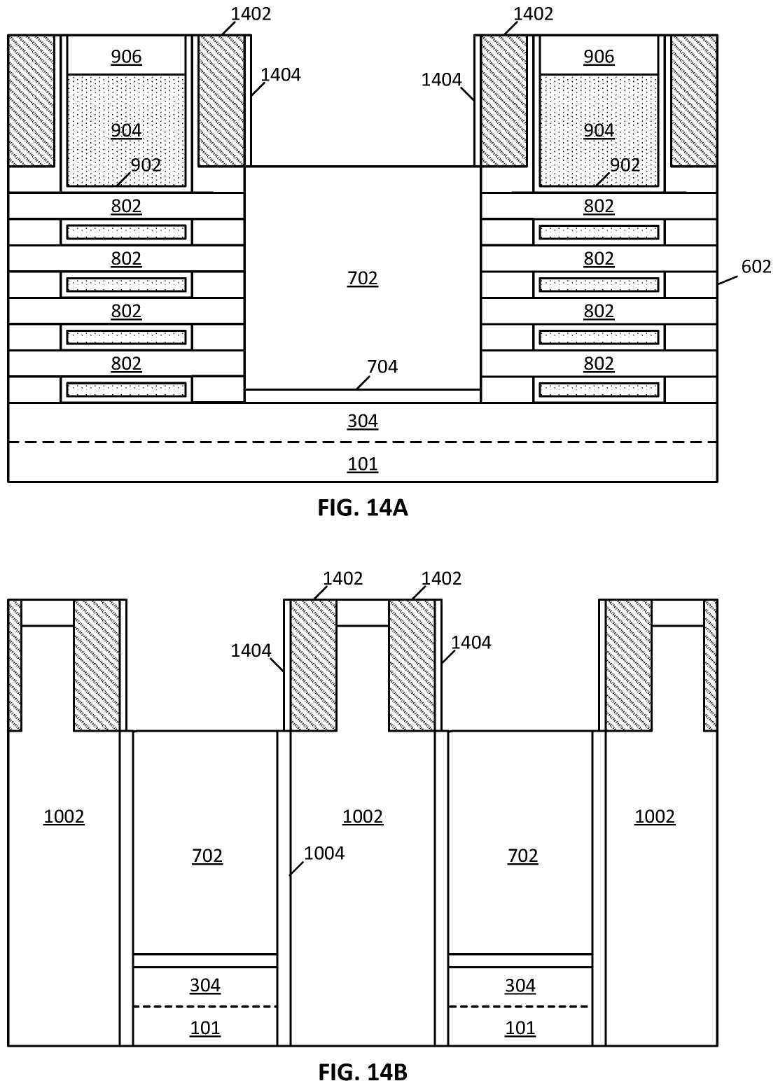

FIGS. 14A and 14B depict cross-section views of the structure shown in FIGS. 13A and 13B, respectively, following the formation of a sacrificial material 1402 along all sidewalls of the widened contact area, according to some embodiments. Sacrificial material 1402 may be deposited along all exposed surfaces and then anisotropically etched back to remain on the sidewalls of structures. Sacrificial material 1402 can be any material that can be safely removed at a later time without damaging surrounding structures. In some examples, sacrificial material 1402 includes aluminum oxide. The lateral width of sacrificial material 1402 extending from the sidewall along either the first direction (FIG. 14A) or the second direction (FIG. 14B) dictates the resulting width of the airgap spacer.

According to some embodiments, a dielectric liner 1404 is deposited over sacrificial material 1402 and similarly etched back to remain on the sidewalls of sacrificial material 1402. Dielectric liner 1404 may be any suitable dielectric material having a high etch selectively with whatever material is used for sacrificial material 1402. In some examples, dielectric liner 1404 includes silicon nitride. According to some embodiments, another dielectric liner may be deposited prior to the formation of sacrificial material 1402 to protect the surface of source or drain regions 702 during the subsequent deposition and etching steps of sacrificial material 1402. This additional dielectric liner may be removed over the top of source or drain regions 702 during the etch back process of dielectric liner 1404.

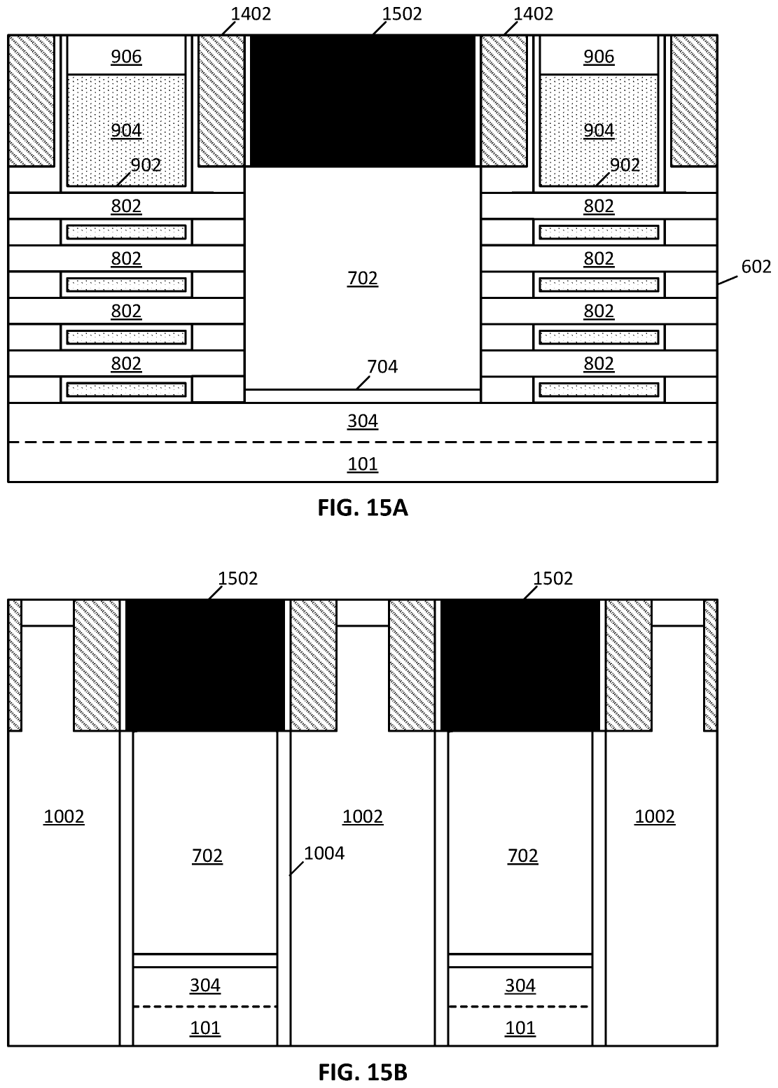

FIGS. 15A and 15B depict cross-section views of the structure shown in FIGS. 14A and 14B, respectively, following the formation of conductive contacts 1502 within the source/drain trench and on any number of source or drain regions 702, according to some embodiments. Contacts 1502 may be formed within the widened contact area such that its perimeter is surrounded by sacrificial material 1402. Contacts 1502 may include any suitable conductive material, such as tungsten, molybdenum, ruthenium, or cobalt for making electrical contact with the underlying source or drain regions 702. According to some embodiments, contacts 1502 include one or more silicide layers directly on the exposed surface of source or drain regions 702. A top surface of contacts 1502 may be polished using any polishing procedure (e.g., chemical mechanical polishing) such that the top surface of contacts 1502 is coplanar with a top surface of sacrificial material 1402 and/or dielectric gate cap 906.

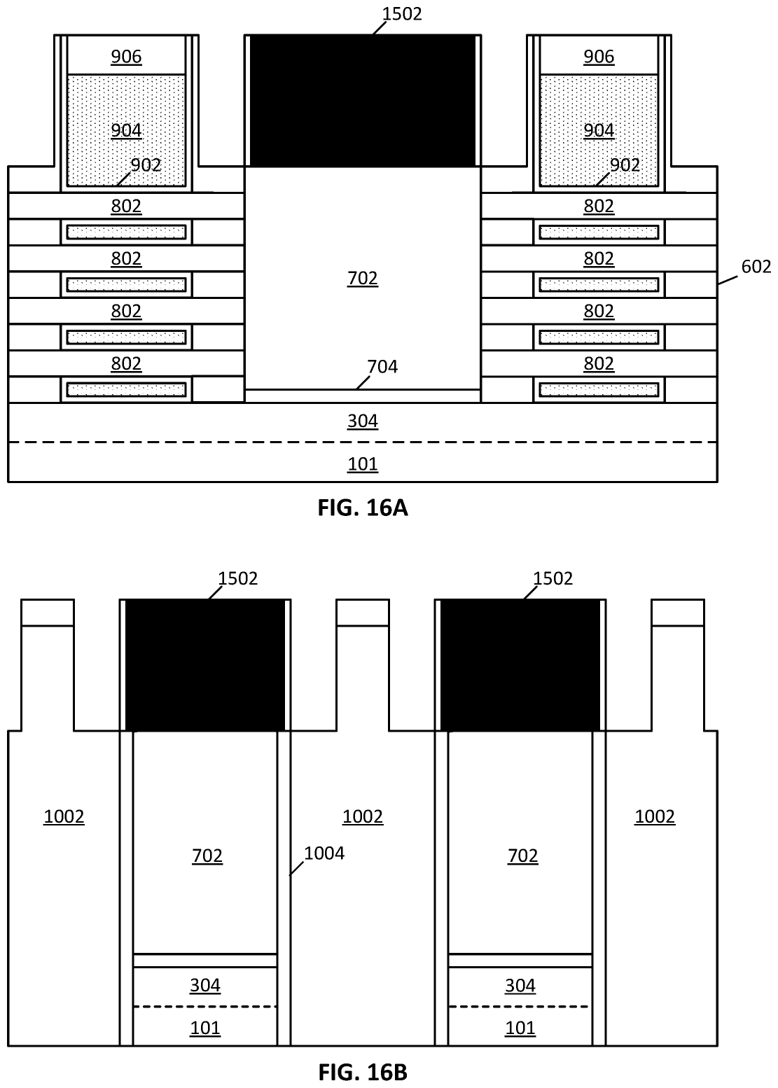

FIGS. 16A and 16B depict cross-section views of the structure shown in FIGS. 15A and 15B, respectively, following the removal of sacrificial material 1402, according to some embodiments. Sacrificial material 1402 may be removed using any suitable isotropic etching process. The removal of sacrificial material 1402 leaves behind an airgap trench that surrounds the perimeter of contacts 1502, according to some embodiments. The width of the airgap trench along the first and second directions may be between about 4 nm and about 6 nm, or between about 6 nm and about 8 nm.

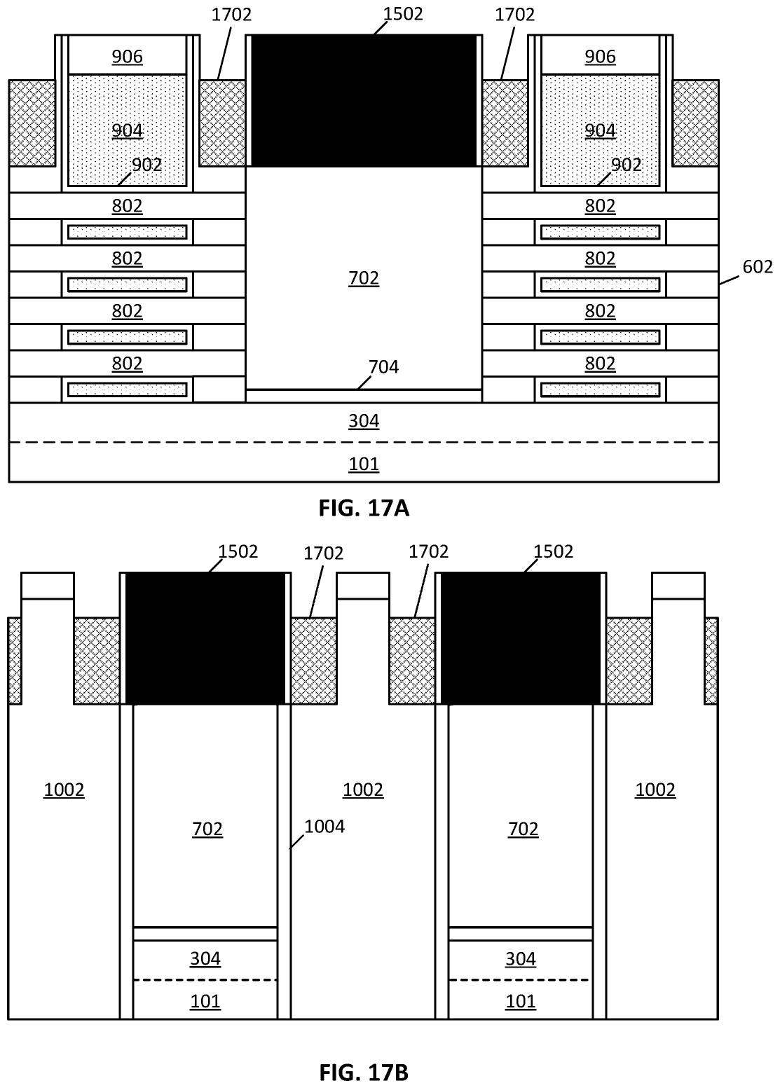

FIGS. 17A and 17B depict cross-section views of the structure shown in FIGS. 16A and 16B, respectively, following the formation of a polymer material 1702 within the airgap trenches, according to an embodiments. Polymer material 1702 can be any suitable carbon-based polymer. Other examples may utilize a material other than a polymer, that can be selectively vaporized to provide airgaps. In some embodiments, polymer material 1702 includes a material that can be sublimated at relatively low temperatures (e.g., less than 500° C.). Polymer material 1702 may be deposited within the airgap trench and subsequently recessed such that a top surface of polymer material 1702 is below a top surface of the adjacent contact 1502. Any suitable isotropic etching process may be used to recess polymer material 1702. In this manner, the height of the resulting airgaps to be subsequently formed may be well-controlled, based on the height of material 1702. In some examples, the height of material 1702 is etched back or otherwise set to be in the range of 5 nm to 25 nm (e.g., 10 nm to 20 nm).

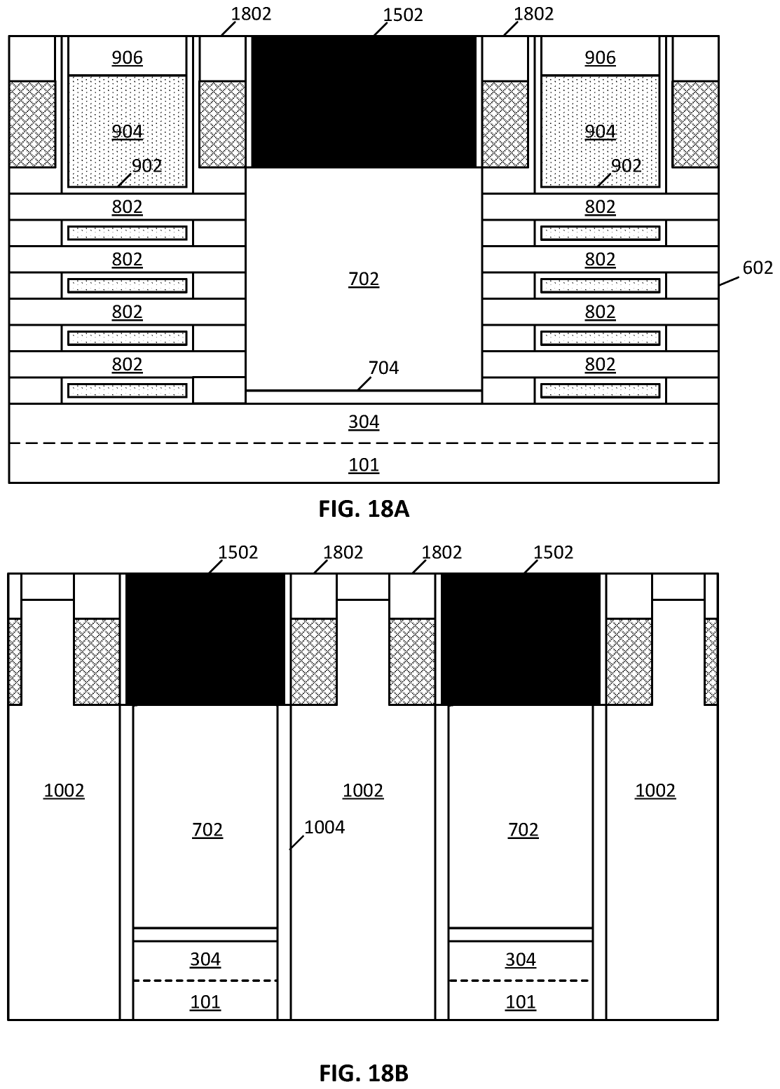

FIGS. 18A and 18B depict cross-section views of the structure shown in FIGS. 17A and 17B, respectively, following the formation of a gap cap layer 1802, according to some embodiments. Gap cap layer 1802 may be formed within the recessed region above polymer material 1702. In some embodiments, a top surface of gap cap layer 1802 may be polished to be substantially coplanar with the adjacent contact 1502 and/or dielectric gate cap 906. According to some embodiments, gap cap layer 1802 includes a dielectric material with enough porosity to allow for outgassing of polymer material 1702 during a subsequent sublimation of polymer material 1702. In some examples, gap cap layer 1802 includes a low-temperature silicon dioxide.

FIGS. 19A and 19B depict cross-section views of the structure shown in FIGS. 18A and 18B, respectively, following the removal of polymer material 1702 to form airgap 1902, according to some embodiments. Polymer material 1702 may be vaporized by applying a temperature between 300° C. and 500° C. for between 1 to 3 hours to sublimate polymer material 1702. The sublimated material may outgas through gap cap layer 1802. The resulting airgap 1902 wraps around an entire perimeter of contacts 1502, according to some embodiments. Additionally, since airgap 1902 was formed via the removal of material rather than forming material, it can be made wider than those made with prior techniques. Airgap 1902 may have a width along both the first direction and the second direction of between about 4 nm and about 6 nm, or larger such as between about 6 nm and about 8 nm. The presence of airgap 1902 between contact 1502 and gate electrode 904 along the first direction and between adjacent contacts 1502 along the second direction reduces the parasitic capacitance in the device, according to some embodiments.

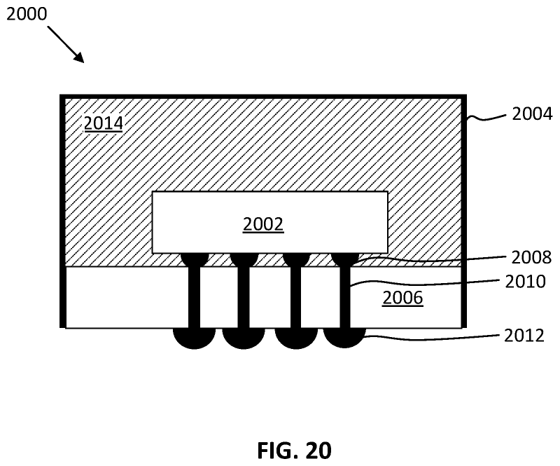

FIG. 20 illustrates an example embodiment of a chip package 2000, in accordance with an embodiment of the present disclosure. As can be seen, chip package 2000 includes one or more dies 2002. One or more dies 2002 may include at least one integrated circuit having semiconductor devices, such as any of the semiconductor devices disclosed herein. One or more dies 2002 may include any other circuitry used to interface with other devices formed on the dies, or other devices connected to chip package 2000, in some example configurations.

As can be further seen, chip package 2000 includes a housing 2004 that is bonded to a package substrate 2006. The housing 2004 may be any standard or proprietary housing, and may provide, for example, electromagnetic shielding and environmental protection for the components of chip package 2000. The one or more dies 2002 may be conductively coupled to a package substrate 2006 using connections 2008, which may be implemented with any number of standard or proprietary connection mechanisms, such as solder bumps, ball grid array (BGA), pins, or wire bonds, to name a few examples. Package substrate 2006 may be any standard or proprietary package substrate, but in some cases includes a dielectric material having conductive pathways (e.g., including conductive vias and lines) extending through the dielectric material between the faces of package substrate 2006, or between different locations on each face. In some embodiments, package substrate 2006 may have a thickness less than 1 millimeter (e.g., between 0.1 millimeters and 0.5 millimeters), although any number of package geometries can be used. Additional conductive contacts 2012 may be disposed at an opposite face of package substrate 2006 for conductively contacting, for instance, a printed circuit board (PCB). One or more vias 2010 extend through a thickness of package substrate 2006 to provide conductive pathways between one or more of connections 2008 to one or more of contacts 2012. Vias 2010 are illustrated as single straight columns through package substrate 2006 for ease of illustration, although other configurations can be used (e.g., damascene, dual damascene, through-silicon via, or an interconnect structure that meanders through the thickness of substrate 2006 to contact one or more intermediate locations therein). In still other embodiments, vias 2010 are fabricated by multiple smaller stacked vias, or are staggered at different locations across package substrate 2006. In the illustrated embodiment, contacts 2012 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 2012, to inhibit shorting.

In some embodiments, a mold material 2014 may be disposed around the one or more dies 2002 included within housing 2004 (e.g., between dies 2002 and package substrate 2006 as an underfill material, as well as between dies 2002 and housing 2004 as an overfill material). Although the dimensions and qualities of the mold material 2014 can vary from one embodiment to the next, in some embodiments, a thickness of mold material 2014 is less than 1 millimeter. Example materials that may be used for mold material 2014 include epoxy mold materials, as suitable. In some cases, the mold material 2014 is thermally conductive, in addition to being electrically insulating.

### Methodology

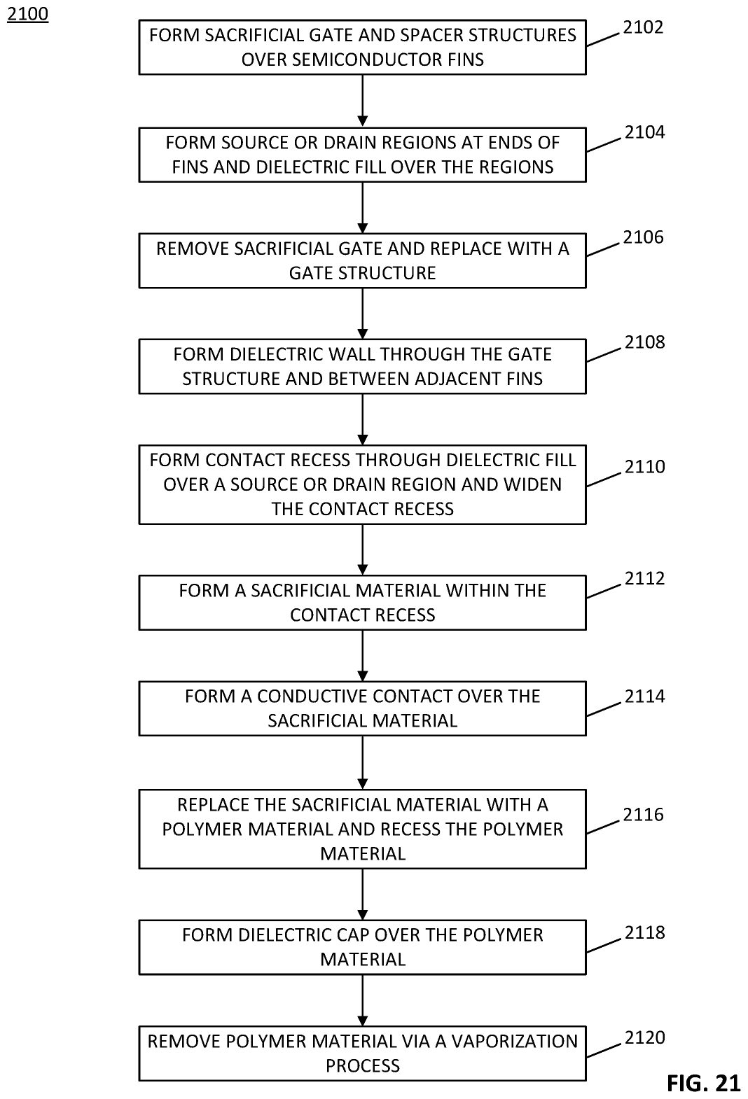

FIG. 21 is a flow chart of a method 2100 for forming at least a portion of an integrated circuit, according to an embodiment. Various operations of method 2100 may be illustrated in FIGS. 2A-19A and 2B-19B. However, the correlation of the various operations of method 2100 to the specific components illustrated in the aforementioned figures is not intended to imply any structural and/or use limitations. Rather, the aforementioned figures provide one example embodiment of method 2100. Other operations may be performed before, during, or after any of the operations of method 2100. For example, method 2100 does not explicitly describe various standard processes that are usually performed to form transistor structures. Some of the operations of method 2100 may be performed in a different order than the illustrated order.

Method 2100 begins with operation 2102 where sacrificial gate and spacer structures are formed over a plurality of parallel semiconductor fins, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may include any suitable dielectric material, such as silicon nitride or silicon oxynitride, or any number of different dielectric layers.

Method 2100 continues with operation 2104 where source or drain regions are formed at opposite ends of the fins. Any exposed portions of the fins not covered by the sacrificial gates or spacer structures may be removed using any anisotropic etching process, such as reactive ion etching (RIE). Once the exposed fins have been removed, the source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe). A dielectric fill may formed between and over the source or drain regions along a given source/drain trench. The dielectric fill may be any suitable dielectric material, such as silicon oxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 2100 continues with operation 2106 where gate structures are formed over the semiconductor material of the various semiconductor fins. The sacrificial gates are first removed along with any sacrificial layers within the exposed fins between the spacer structures (in the case of GAA structures). The gate structures may then be formed in place of the sacrificial gates. The gate structures may each include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

Method 2100 continues with operation 2108 where a dielectric wall is formed through the gate structure between an adjacent pair of fins. According to some embodiments, a trench is etched through both the gate structure and through the dielectric fill around the source or drain regions. The trench may extend lengthwise in the same direction (e.g., first direction) as the length of the fins or nanowires. Multiple parallel trenches may be formed in this way to ultimate produce any number of parallel dielectric walls. A single etching process may be used to form all of the trenches through a mask with a grating pattern. A reactive ion etching (RIE) process may be used to cut through the various material layers and form the trench. The dielectric wall extends between the gate structures and between the source or drain regions of adjacent devices. According to some embodiments, the dielectric wall includes a dielectric liner and a dielectric fill on the dielectric liner.

Method 2100 continues with operation 2110 where a contact recess is formed over a given source or drain region and subsequently widened along both the first and second directions. According to some embodiments, the dielectric fill over the source or drain regions may be recessed at least until a top surface of the source or drain regions in the trench are exposed. Afterwards, the dielectric sidewalls of the contact recess may be trimmed back to widen the contact recess. For example, portions of the dielectric spacers may be etched or have certain dielectric layers removed to widen the contact recess along the first direction. Similarly, the dielectric fill of the dielectric walls may be laterally etched using an isotropic etching process to widen the contact recess along the second direction.

Method 2100 continues with operation 2112 where a sacrificial material is formed within the contact recess. According to some embodiments, the sacrificial material is deposited everywhere and then etched back to remain only on the sidewalls of the contact recess. The sacrificial material can be any material that can be safely removed at a later time without damaging surrounding structures. In some examples, the sacrificial material includes aluminum oxide.

Method 2100 continues with operation 2114 where a conductive contact is formed within the contact recess such that the conductive contact touches the top surface of the givens source or drain region. According to some embodiments, an entire perimeter of the conductive contact is surrounded by the sacrificial material. There may be a dielectric liner, such as silicon nitride, directly present between the conductive contact and the sacrificial material. The conductive contact may include any suitable conductive material, such as tungsten, molybdenum, ruthenium, or cobalt.

Method 2100 continues with operation 2116 where the sacrificial material around the conductive contact is replaced with a polymer material. According to some embodiments, the sacrificial material is removed using any suitable isotropic etching process and the trench left behind is filled with a low-temperature carbon-based polymer material. In some embodiments, the polymer material includes a material that can be sublimated at relatively low temperatures (e.g., less than 500° C.). The polymer material may be deposited within the trench around the contact and subsequently recessed such that a top surface of the polymer material is below a top surface of the adjacent contact. Any suitable isotropic etching process may be used to recess the polymer material.

Method 2100 continues with operation 2118 where a dielectric cap is formed over the polymer material. According to some embodiments, the dielectric cap may be formed within the recessed region above the polymer material. In some embodiments, a top surface of the dielectric cap may be polished to be substantially coplanar with the adjacent contact. According to some embodiments, the dielectric cap includes a dielectric material with enough porosity to allow for outgassing of the polymer material during a subsequent sublimation of the polymer material. In some examples, the dielectric cap includes a low-temperature silicon dioxide.

Method 2100 continues with operation 2120 where the polymer material is removed to form an airgap. According to some embodiments, the polymer material is sublimated via a vaporization process by applying a temperature between 300° C. and 500° C. for 1 to 3 hours. The sublimated material may outgas through the dielectric cap. The resulting airgap wraps around an entire perimeter of the adjacent contact, according to some embodiments.

### Example System

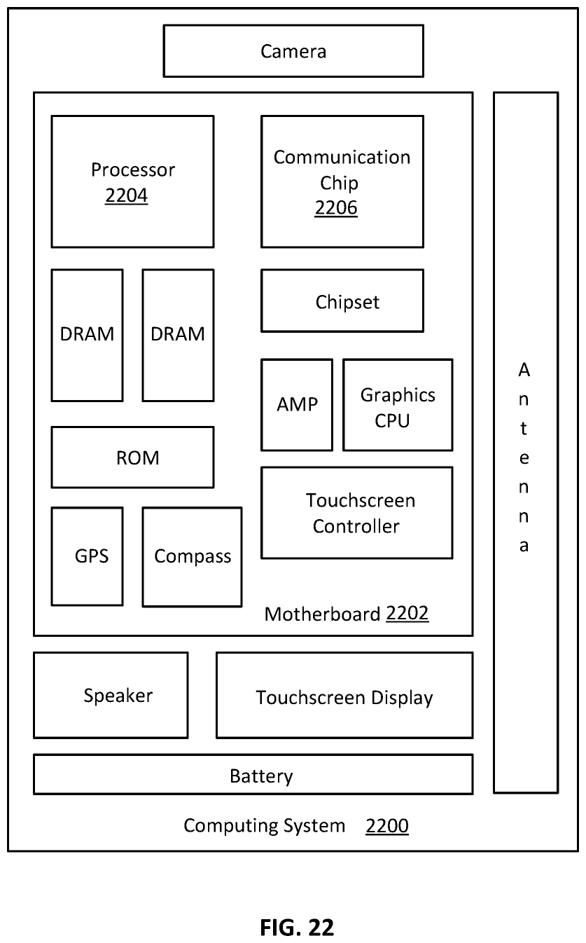

FIG. 22 is an example computing system implemented with one or more of the integrated circuit structures as disclosed herein, in accordance with some embodiments of the present disclosure. As can be seen, the computing system 2200 houses a motherboard 2202. The motherboard 2202 may include a number of components, including, but not limited to, a processor 2204 and at least one communication chip 2206, each of which can be physically and electrically coupled to the motherboard 2202, or otherwise integrated therein. As will be appreciated, the motherboard 2202 may be, for example, any printed circuit board (PCB), whether a main board, a daughterboard mounted on a main board, or the only board of system 2200, etc.

Depending on its applications, computing system 2200 may include one or more other components that may or may not be physically and electrically coupled to the motherboard 2202. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2200 may include one or more integrated circuit structures or devices configured in accordance with an example embodiment (e.g., a contact structure having a circumferential airgap spacer surrounding it, as variously provided herein). In some embodiments, multiple functions can be integrated into one or more chips (e.g., for instance, note that the communication chip 2206 can be part of or otherwise integrated into the processor 2204).

The communication chip 2206 enables wireless communications for the transfer of data to and from the computing system 2200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2206 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2200 may include a plurality of communication chips 2206. For instance, a first communication chip 2206 may be dedicated to shorter range wireless communications such as Wi-Fi and Bluetooth and a second communication chip 2206 may be dedicated to longer range wireless communications such as GPS, EDGE, GPRS, CDMA, WiMAX, LTE, Ev-DO, and others.

The processor 2204 of the computing system 2200 includes an integrated circuit die packaged within the processor 2204. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2206 also may include an integrated circuit die packaged within the communication chip 2206. In accordance with some such example embodiments, the integrated circuit die of the communication chip includes one or more semiconductor devices as variously described herein. As will be appreciated in light of this disclosure, note that multi-standard wireless capability may be integrated directly into the processor 2204 (e.g., where functionality of any chips 2206 is integrated into processor 2204, rather than having separate communication chips). Further note that processor 2204 may be a chip set having such wireless capability. In short, any number of processor 2204 and/or communication chips 2206 can be used. Likewise, any one chip or chip set can have multiple functions integrated therein.

In various implementations, the computing system 2200 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2200 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region, and a gate structure extending in a second direction over the semiconductor region. A conductive contact is on a top surface of the source or drain region, and a dielectric structure extends along the first direction and through an entire thickness of the gate structure in a third direction such that the dielectric structure is spaced from the conductive contact along the second direction. An airgap is between the conductive contact and the gate structure along the first direction and between the conductive contact and the dielectric structure along the second direction.

Example 2 includes the integrated circuit of Example 1, wherein the dielectric structure comprises a high-k dielectric material.

Example 3 includes the integrated circuit of Example 1 or 2, wherein the airgap has a lateral thickness along the first direction between the conductive contact and the gate structure of between about 4 nm and about 6 nm, and the airgap has a lateral thickness along the second direction between the conductive contact and the dielectric structure of between about 4 nm and about 6 nm.

Example 4 includes the integrated circuit of any one of Examples 1-3, wherein the airgap has a vertical height along the third direction between the conductive contact and the gate structure of between about 10 nm and about 20 nm, and the airgap has a vertical height along the third direction between the conductive contact and the dielectric structure of between about 10 nm and about 20 nm.

Example 5 includes the integrated circuit of any one of Examples 1-4, further comprising a first dielectric layer between the conductive contact and the airgap along the first and second directions, and a second dielectric layer between the airgap and the gate structure along the first direction.

Example 6 includes the integrated circuit of Example 5, wherein the first and second dielectric layers each comprise silicon and nitrogen.

Example 7 includes the integrated circuit of any one of Examples 1-6, wherein the dielectric structure is a first dielectric structure, and the integrated circuit further comprises a second dielectric structure extending along the first direction and through an entire thickness of the gate structure in the third direction, the second dielectric structure being spaced from an opposite side of the conductive contact along the second direction compared to the first dielectric structure.

Example 8 includes the integrated circuit of Example 7, wherein the airgap is also between the conductive contact and the second dielectric structure along the second direction.

Example 9 includes the integrated circuit of Example 7 or 8, wherein the airgap extends into a portion of the dielectric structure.

Example 10 includes the integrated circuit of any one of Examples 7-9, wherein the airgap extends into an upper portion of the first dielectric structure and into an upper portion of the second dielectric structure, such that the upper portion of the first dielectric structure is at least 4 nm to 6 nm thinner than a lower portion of the first dielectric structure, and such that the upper portion of the second dielectric structure is at least 4 nm to 6 nm thinner than a lower portion of the second dielectric structure.

Example 11 includes the integrated circuit of any one of Examples 1-10, further comprising a dielectric cap over the airgap, wherein the dielectric cap is adjacent to the conductive contact along the first and/or second direction.

Example 12 includes the integrated circuit of any one of Examples 1-11, wherein the first direction is perpendicular to the second direction, and the third direction is perpendicular to both the first and second directions.

Example 13 includes the integrated circuit of any one of Examples 1-12, wherein the airgap extends into a portion of the dielectric structure.

Example 14 includes the integrated circuit of any one of Examples 1-13, wherein the airgap extends into an upper portion of the dielectric structure, such that the upper portion of the dielectric structure is at least 4 nm to 6 nm thinner than the underlying portion of the dielectric structure.

Example 15 is a printed circuit board that includes the integrated circuit of any one of Examples 1-14.

Example 16 is an electronic device that includes a chip package having one or more dies. At least one of the one or more dies includes a semiconductor region extending in a first direction from a first source or drain region to a second source or drain region, a gate structure extending in a second direction over the semiconductor region, a conductive contact on a top surface of the first source or drain region, a dielectric structure extending along the first direction and through an entire thickness of the gate structure in a third direction, and an airgap between the conductive contact and the gate structure along the first direction and between the conductive contact and the dielectric structure along the second direction. The dielectric structure is spaced from the conductive contact along the second direction.

Example 17 includes the electronic device of Example 16, wherein the dielectric structure comprises a high-k dielectric material.

Example 18 includes the electronic device of Example 16 or 17, wherein the airgap has a lateral thickness along the first direction between the conductive contact and the gate structure of between about 4 nm and about 6 nm, and the airgap has a lateral thickness along the second direction between the conductive contact and the dielectric structure of between about 4 nm and about 6 nm.

Example 19 includes the electronic device of any one of Examples 16-18, wherein the at least one of the one or more dies further comprises a first dielectric layer between the conductive contact and the airgap along the first and second directions, and a second dielectric layer between the airgap and the gate structure along the first direction.

Example 20 includes the electronic device of Example 19, wherein the first and second dielectric layers each comprise silicon and nitrogen.

Example 21 includes the electronic device of any one of Examples 16-20, wherein the dielectric structure is a first dielectric structure, and the at least one of the one or more dies further comprises a second dielectric structure extending along the first direction and through an entire thickness of the gate structure in the third direction, the second dielectric structure being spaced from an opposite side of the conductive contact along the second direction compared to the first dielectric structure.

Example 22 includes the electronic device of Example 21, wherein the airgap is also between the conductive contact and the second dielectric structure along the second direction.

Example 23 includes the electronic device of any one of Examples 16-22, wherein the at least one of the one or more dies further comprises a dielectric cap over the airgap, wherein the dielectric cap is adjacent to the conductive contact along the first and/or second direction.

Example 24 includes the electronic device of any one of Examples 16-23, wherein the first direction is perpendicular to the second direction, and the third direction is perpendicular to both the first and second directions.

Example 25 includes the electronic device of any one of Examples 16-24, further comprising a printed circuit board, wherein the chip package is coupled to the printed circuit board.

Example 26 is a method of forming an integrated circuit. The method includes forming a fin comprising semiconductor material, the fin extending above a substrate and extending in a first direction; forming a dielectric layer adjacent to a subfin portion of the fin; forming source or drain regions at opposite ends of the fin; forming a dielectric fill over the source or drain regions; forming a gate structure on the dielectric layer and over the semiconductor material and extending in a second direction; recessing the dielectric fill over the source or drain region to form a contact recess that exposes a top surface of the source or drain region; forming a sacrificial material within the contact recess; forming a conductive contact over the sacrificial material within the contact recess; replacing the sacrificial material with a polymer material; recessing a top portion of the polymer material; forming a dielectric cap within the recessed area above the polymer material; and removing the polymer material via a vaporization process to leave behind an airgap in the volume previously occupied by the polymer material.

Example 27 includes the method of Example 26, further comprising forming a dielectric structure extending in the first direction and through an entire thickness of the gate structure in a third direction, wherein the contact recess is directly adjacent to a sidewall of the dielectric structure.

Example 28 includes the method of Example 26 or 27, further comprising forming a first dielectric layer within the contact recess prior to the formation of the sacrificial material; and forming a second dielectric layer within the contact recess on the polymer material prior to the formation of the conductive contact.

Example 29 includes the method of any one of Examples 26-28, wherein removing the polymer material comprises vaporizing the polymer material at a temperature of 300° C.-500° C.

Example 30 includes the method of any one of Examples 26-29, wherein forming the dielectric cap comprises forming a dielectric liner directly on the polymer material and forming a dielectric material on the dielectric liner.

Example 31 includes the method of any one of Examples 26-30, wherein the sacrificial material comprises aluminum and oxygen.

Example 32 is an integrated circuit that includes a first semiconductor device having a first semiconductor region extending in a first direction from a source or drain region, and a first gate structure extending in a second direction over the first semiconductor region. The integrated circuit further includes a second semiconductor device having a second semiconductor region extending in the first direction from an opposite side of the source or drain region compared to the first semiconductor region, and a second gate structure extending in the second direction over the second semiconductor region. The integrated circuit further includes a conductive contact on a top surface of the source or drain region, a first dielectric structure extending along the first direction through an entire thickness of both the first gate structure and the second gate structure in a third direction, and a second dielectric structure extending along the first direction through an entire thickness of both the first gate structure and the second gate structure in the third direction. The integrated circuit further includes an airgap around the conductive contact such that the airgap is between the conductive contact and the first gate structure along the first direction, between the conductive contact and the second gate structure along the first direction, between the conductive contact and the first dielectric structure along the second direction, and between the conductive contact and the second dielectric structure along the second direction.

Example 33 includes the integrated circuit of Example 32, wherein the first and second dielectric structures each comprise a high-k dielectric material.

Example 34 includes the integrated circuit of Example 32 or 33, wherein the airgap has a lateral thickness along the first direction between about 4 nm and about 6 nm and a lateral thickness along the second direction between about 4 nm and about 6 nm.

Example 35 includes the integrated circuit of any one of Examples 32-34, further comprising a first dielectric layer between the conductive contact and the airgap along the first and second directions, and a second dielectric layer between the airgap and the first and second gate structures along the first direction.

Example 36 includes the integrated circuit of Example 35, wherein the first and second dielectric layers each comprise silicon and nitrogen.

Example 37 includes the integrated circuit of any one of Examples 32-36, further comprising a dielectric cap over the airgap, wherein the dielectric cap is adjacent to the conductive contact along the first and second directions.

Example 38 includes the integrated circuit of any one of Examples 32-37, wherein the first direction is perpendicular to the second direction.

Example 39 is a printed circuit board that includes the integrated circuit of any one of Examples 32-38.

Example 40 is an integrated circuit that includes a first semiconductor device having a first semiconductor region extending in a first direction from a first source or drain region, and a gate structure extending in a second direction over the first semiconductor region, a second semiconductor device having a second semiconductor region extending in the first direction from a second source or drain region, a first conductive contact on a top surface of the first source or drain region, a second conductive contact on a top surface of the second source or drain region, a dielectric structure extending along the first direction and between the first contact and the second contact, a first airgap around the first conductive contact and extending into a first side of the dielectric wall, and a second airgap around the second conductive contact and extending into a second side of the dielectric wall.

Example 41 includes the integrated circuit of Example 40, wherein the dielectric structure comprises a high-k dielectric material.

Example 42 includes the integrated circuit of Example 40 or 41, wherein each of the first and second airgaps has a lateral thickness along the first direction between about 4 nm and about 6 nm and a lateral thickness along the second direction between about 4 nm and about 6 nm.

Example 43 includes the integrated circuit of any one of Examples 40-42, further comprising a first dielectric layer between the first conductive contact and the first airgap along the first and second directions, and a second dielectric layer between the second conductive contact and the second airgap along the first and second directions.

Example 44 includes the integrated circuit of Example 43, wherein the first and second dielectric layers each comprise silicon and nitrogen.

Example 45 includes the integrated circuit of any one of Examples 40-44, further comprising: a first dielectric cap over the first airgap, the first dielectric cap being adjacent to the first conductive contact along the first and second directions; and a second dielectric cap over the second airgap, the second dielectric cap being adjacent to the second conductive contact along the first and second directions.

Example 46 includes the integrated circuit of any one of Examples 40-45, wherein the first direction is perpendicular to the second direction.

Example 47 includes the integrated circuit of any one of Examples 40-46, wherein a first portion of the dielectric structure between the first and second airgaps is 8 nm to 12 nm thinner than a thickness of a second portion of the dielectric wall, the second portion being below the first portion.

Example 48 is a printed circuit board that includes the integrated circuit of any one of Examples 40-47.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region;
a conductive contact on a top surface of the source or drain region;
a dielectric structure extending along the first direction and through an entire thickness of the gate structure in a third direction, the dielectric structure being spaced from the conductive contact along the second direction; and
an airgap between the conductive contact and the gate structure along the first direction and between the conductive contact and the dielectric structure along the second direction.

2. The integrated circuit of claim 1, wherein the dielectric structure comprises a high-k dielectric material.

3. The integrated circuit of claim 1, wherein the airgap has a lateral thickness along the first direction between the conductive contact and the gate structure of between about 4 nm and about 6 nm, and the airgap has a lateral thickness along the second direction between the conductive contact and the dielectric structure of between about 4 nm and about 6 nm.

4. The integrated circuit of claim 1, wherein the airgap has a vertical height along the third direction between the conductive contact and the gate structure of between about 10 nm and about 20 nm, and the airgap has a vertical height along the third direction between the conductive contact and the dielectric structure of between about 10 nm and about 20 nm.

5. The integrated circuit of claim 1, wherein the dielectric structure is a first dielectric structure, and the integrated circuit further comprises a second dielectric structure extending along the first direction and through an entire thickness of the gate structure in the third direction, the second dielectric structure being spaced from an opposite side of the conductive contact along the second direction compared to the first dielectric structure.

6. The integrated circuit of claim 5, wherein the airgap is also between the conductive contact and the second dielectric structure along the second direction.

7. The integrated circuit of claim 1, further comprising a dielectric cap over the airgap, wherein the dielectric cap is adjacent to the conductive contact along the first and/or second direction.

8. A printed circuit board comprising the integrated circuit of claim 1.

9. An integrated circuit comprising:
a first semiconductor device having a first semiconductor region extending in a first direction from a source or drain region, and a first gate structure extending in a second direction over the first semiconductor region;
a second semiconductor device having a second semiconductor region extending in the first direction from an opposite side of the source or drain region compared to the first semiconductor region, and a second gate structure extending in the second direction over the second semiconductor region;
a conductive contact on a top surface of the source or drain region;
a first dielectric structure extending along the first direction through both the first gate structure and the second gate structure;
a second dielectric structure extending along the first direction through both the first gate structure and the second gate structure; and
an airgap around the conductive contact such that the airgap is between the conductive contact and the first gate structure along the first direction, between the conductive contact and the second gate structure along the first direction, between the conductive contact and the first dielectric structure along the second direction, and between the conductive contact and the second dielectric structure along the second direction.

10. The integrated circuit of claim 9, wherein the airgap has a lateral thickness along the first direction between about 4 nm and about 6 nm and a lateral thickness along the second direction between about 4 nm and about 6 nm.

11. The integrated circuit of claim 9, further comprising a first dielectric layer between the conductive contact and the airgap along the first and second directions, and a second dielectric layer between the airgap and the first and second gate structures along the first direction.

12. The integrated circuit of claim 11, wherein the first and second dielectric layers each comprise silicon and nitrogen.

13. The integrated circuit of claim 9, further comprising a dielectric cap over the airgap, wherein the dielectric cap is adjacent to the conductive contact along the first and second directions.

14. The integrated circuit of claim 9, wherein the first direction is perpendicular to the second direction.

15. An integrated circuit comprising:
a first semiconductor device having a first semiconductor region extending in a first direction from a first source or drain region, and a gate structure extending in a second direction over the first semiconductor region;
a second semiconductor device having a second semiconductor region extending in the first direction from a second source or drain region;
a first conductive contact on a top surface of the first source or drain region;
a second conductive contact on a top surface of the second source or drain region;
a dielectric structure extending along the first direction and between the first contact and the second contact;
a first airgap around the first conductive contact and extending into a first side of the dielectric structure; and
a second airgap around the second conductive contact and extending into a second side of the dielectric structure.

16. The integrated circuit of claim 15, wherein each of the first and second airgaps has a lateral thickness along the first direction between about 4 nm and about 6 nm and a lateral thickness along the second direction between about 4 nm and about 6 nm.

17. The integrated circuit of claim 15, further comprising a first dielectric layer between the first conductive contact and the first airgap along the first and second directions, and a second dielectric layer between the second conductive contact and the second airgap along the first and second directions.

18. The integrated circuit of claim 15, further comprising: a first dielectric cap over the first airgap, the first dielectric cap being adjacent to the first conductive contact along the first and second directions; and a second dielectric cap over the second airgap, the second dielectric cap being adjacent to the second conductive contact along the first and second directions.

19. The integrated circuit of claim 15, wherein the first direction is perpendicular to the second direction.

20. The integrated circuit of claim 15, wherein a first portion of the dielectric structure between the first and second airgaps is 8 nm to 12 nm thinner than a thickness of a second portion of the dielectric wall, the second portion being below the first portion.
